(19) United States
(12) Patent Application Publication
(10) Pub. No.: US 2015/0310998 A1
(43) Pub. Date: Oct. 29, 2015

(54) COBALT COMPLEXES WITH TRICYANOBORATE OR DICYANOBORATE COUNTER-ANIONS FOR ELECTROCHEMICAL OR OPTOELECTRONIC DEVICES

(71) Applicant: Merck Patent GmbH, Darmstadt (DE)

(72) Inventors: Nikolai (Mykola) IGNATYEV, Duisburg (DE); Michael SCHULTE, Bischofsheim (DE); Kentaro KAWATA, Kanagawa (JP)

(73) Assignee: Merck Patent GmbH, Darmstadt (DE)

(21) Appl. No.: 14/647,503

(22) PCT Filed: Nov. 4, 2013
(86) PCT No.: PCT/EP2013/003310

§ 371 Date: May 27, 2015

(30) Foreign Application Priority Data
Nov. 30, 2012 (EP) 12008061.9

(51) Int. Cl. H01G 9/20; H01L 51/00; C07F 15/06

(52) U.S. Cl. CPC H01G 9/2059; C07F 15/065; H01L 51/0083

(57) ABSTRACT

The present invention relates to Cobaltcomplex salts and their use as redox active species or dopant for hole transport materials in electrochemical and/or optoelectronic devices. The present invention relates additionally to electrochemical and/or optoelectronic devices comprising said salts and electrolyte formulations comprising said salts.

### FIELD OF THE INVENTION

The present invention relates to Cobaltcomplex salts according to formula (I) as described below and their use as redox active species or dopant for hole transport materials in electrochemical and/or optoelectronic devices. The present invention relates additionally to electrochemical and/or optoelectronic devices comprising said salts and electrolyte formulations comprising said salts.

### BACKGROUND OF THE INVENTION

Dye-sensitized solar cells (DSSCs) are considered to be a promising alternative to cost-intensive silicon based photovoltaic devices. The working principle of a dye-sensitized solar cell is similar to that which Nature use in the leaves of the plants to convert carbon dioxide and water into carbohydrates and oxygen under sunlight. Chlorophyll in the leaves sensitize this process in the Nature. The first artificial sensitized solar cell was fabricated by covering titanium dioxide crystals with a layer of Chlorophyll.

Modern dye-sensitized solar cells are multicomponent systems which consist of semiconductor anode (an oxide, typically TiO₂, anatase), dye-sensitizer, counter-electrode (cathode) and electrolyte which contains a redox active species, solvent and some additives. The photoanode is constituted by a monolayer of a molecular redox dye sensitizer adsorbed onto a layer of nanocrystalline semiconductor nanoparticles. After light absorption, an excited state of the photosensitizer readily inject an electron into the conduction band of the semiconductor. The electron back transfer from the conduction band to dye cations is named interfacial charge recombination. This interfacial charge recombination competes kinetically with the reaction of the redox active species with the oxidized sensitizer. The redox active species becomes oxidized and the sensitizer becomes reduced and ready to be able to absorb light again. The reduction of the redox active species takes place in the charge transport layer, e.g. by the electrolyte formulation. The redox active species is often called mediator or redox shuttle and build a so-called redox couple. Charge transport by the electrolyte in the pores of the semiconductor film to the counter electrode and that of injected electrons within the nanocrystalline film to the back contact should be fast enough to compete efficiently with the electron recapture reaction [H. Nusbaumer et al, J. Phys. Chem. B2001, 105, 10461-10464]. In spite of DSSCs already achieved solar-to-electric power-conversion efficiency (PCE, η) of more than 11% (under standard air mass 1.5 and solar light intensity 1000 W/m² at 298 K), they are still a factor of 2 below that of Si-solar cells [J.-H. Yum, E. Baranoff, F. Kessler, T. Moehl, S. Ahmad, T. Bessho, A. Marchioro, E. Ghadiri, J.-E. Moser, C. Yi, Md. K. Nazeeruddin and M. Grätzel, Nature Communications, 3 (2012), p. 631]. For further improvement of the PCE the optimization of all components of DSSC and in particular of redox mediators are required. Electrolytes containing the I⁻/I₃⁻ redox system are commonly used in DSSC as the redox active species or mediator. However the I⁻/I₃⁻ redox couple suffers from a low redox potential which limits the open-circuit potential to 0.7-0.8 V of this type of DSSC. [H. N. Tsao, C. Yi, T. Moehl, J.-H. Yum, S. M. Zakeeruddin, M. K. Nazeeruddin and M. Grätzel, ChemSusChem, 4 (2011), p. 591-594.] Iodide-containing electrolytes also corrode current collectors in DSSC made from Ag or Cu. Therefore, the development of non-corrosive electrolytes with redox active species which better correspond to the oxidation potential of the dye is required.

Recently, several publications devoted to the use of cobalt redox shuttles, e.g. cobalt (III/II) tris(2,2′-bipyridine), in electrolyte formulations for DSSC or within the charge-transfer layer of solid state DSSC (sDSSC).

It is known that the oxidation of Co(II)-complexes and the reduction of Co(III)-complexes depend on the counter-anion and on the nature of the ligands coordinated on the metal centre. A variety of ligands to stabilize the oxidation state of Co(II) and Co(III) have been developed and studied [N. N. Greenwood, A. Earnshaw, Chemistry of the Elements, Band 2, Part 26. Cobalt, Rhodium, Iridium, 1997, Elsevier Science Ltd.]. Co(II)/(III)-complexes are known with variety of anions, for instance with [PF₆]⁻ [WO 2012/001033; H.-S. Kim, S.-B. Ko, I.-H. Jang and N.-G. Park, Chem. Commun., 47 (2011), p. 12637-12639; J.-H. Yum, E. Baranoff, F. Kessler, T. Moehl, S. Ahmad, T. Bessho, A. Marchioro, E. Ghadiri, J.-E. Moser, C. Yi, Md. K. Nazeeruddin and M. Grätzel, Nature Communications, 3 (2012), p. 631], [(CF₃SO₂)₂N]⁻ [P. Nockemann, M. Pellens, K. V. Hecke, L. V. Meervelt, J. Wouters, B. Thijs, E. Vanecht, T. N. Parac-Vogt, N. Mehdi, S. Schaltin, J. Fransaer, S. Zahn, B. Kirchner and K. Binnemans, Chem. Eur. J., 16 (2010), p. 1849-1858] and [B(CN)₄]⁻ [WO 2012/114315; A. Yella, H.-W. Lee, H. N. Tsao, C. Yi, A. K. Chadrian, Md. K. Nazeeruddin, E. W.-G. Diau, C.-Y. Yeh, S. M. Zakeeruddin, M. Grätzel, Science, 334 (2011), p. 629-634; H. N. Tsao, J. Burschka, C. Yi, F. Kessler, M. K. Nazeeruddin and M. Grätzel, Energy Environ. Sci., 4 (2011), p. 4921-4924; H. N. Tsao, C. Yi, T. Moehl, J.-H. Yum, S. M. Zakeeruddin, M. K. Nazeeruddin and M. Grätzel, ChemSusChem, 4 (2011), p. 591-594].

However, there continues to be a demand for new and/or improved redox shuttles for electrochemical and optoelectronic devices.

The objective of the invention is therefore to provide an alternative and/or improved redox couple for electrochemical and optoelectronic devices.

### PRESENT INVENTION

Surprisingly, it was found that replacement of tetracyanoborate-anion in Co(III/II) complexes with less symmetrical anions containing a reduced number of cyano-groups results in new Co(II)/(III)-complexes which provide better performance of DSSC.

The present invention therefore relates firstly to compounds of formula (I)

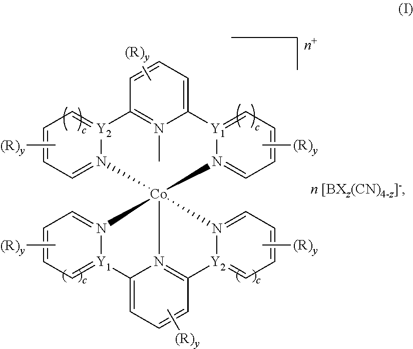

in which

X is H or F,

Y₁ and Y₂ are each independently C or N,

c is 0 in the case Y₁ and/or Y₂ are N,

c is 1 in the case Y₁ and/or Y₂ are C,

z is 1 or 2,

n is 2 or 3,

y is each independently 0, 1, 2, 3 or 4,

R is each independently a straight-chain or branched alkyl group with 1 to 20 C atoms.

Compounds of formula (I) are defined in such a way that the given formula (I) comprises all possible stereoisomeric forms.

A straight-chain or branched alkyl group having 1 to 20 C atoms is, for example, methyl, ethyl, propyl, isopropyl, n-butyl, sec.-butyl, tert.-butyl, 1-(2,2-dimethyl)-propyl, pentyl, hexyl, heptyl, octyl, x-methylbutyl with x being 1; 2 or 3, x-methylpentyl with x being 1; 2; 3 or 4, x-methylhexyl with x being 1; 2; 3; 4 or 5, x-ethylpentyl with x being 1, 2 or 3, x-ethylhexyl with x being 1; 2; 3 or 4, n-nonyl, n-decyl, n-undecyl, n-dodecyl, n-tridecyl, n-tetradecyl, n-pentadecyl, n-hexadecyl, n-heptadecyl, n-octadecyl, n-nonadecyl and n-eicosyl. Preferably, the straight-chain or branched alkyl group has 1 to 10 C atoms. Particularly preferably, the straight-chain or branched alkyl group is methyl, ethyl, isopropyl, n-butyl, sec.-butyl or tert.-butyl. Very particularly preferably, the straight-chain or branched alkyl group is methyl or tert.-butyl.

Compounds of formula (I) having anions of the formula [BX_{z}(CN)_{4-Z},]⁻ in which X is H or F and z is 1 or 2 correspond therefore to compounds of formula (IA) in which X is H and z is 1

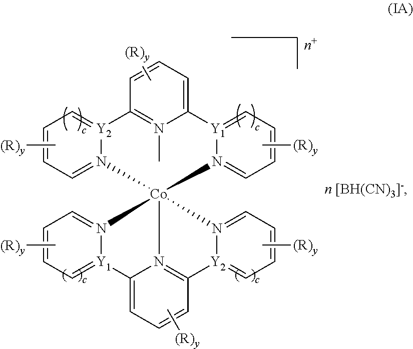

compounds of formula (IB) in which X is H and z is 2

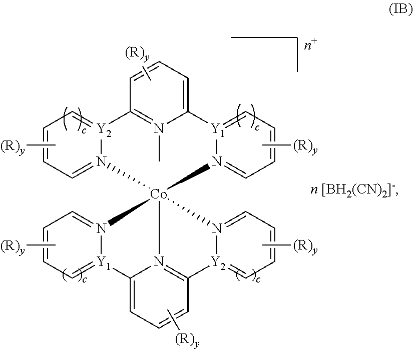

compounds of formula (IC) in which X is F and z is 1

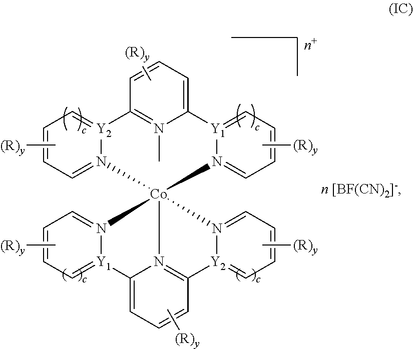

and compounds of formula (ID) in which X is F and z is 2

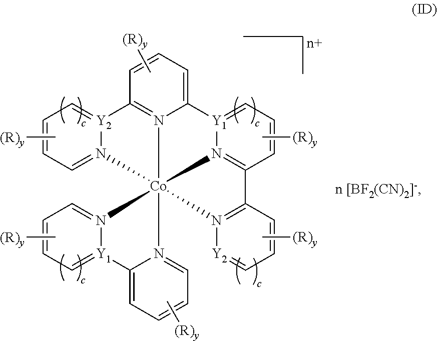

wherein Y₁, Y₂, c, R, y and n have a meaning as described above or below.

Compounds of formula (IA), (IB), (IC), (ID) are defined in such a way that the given formulae comprise all possible stereoisomeric forms.

The invention furthermore relates to the use of at least one compound of formula (I), (IA), (IB), (IC) or (ID) as redox active species.

Therefore, the term “Co^{II}/Co^{III}-redox couple of formula (I)” is defined as the mixture of the compound of formula (I) in which n is 2 with the compound of formula (I) in which n is 3 and the substituents Y₁, Y₂, c, X, z, R, y and n are identical or different.

The Co^{II}/Co^{III}-redox couple of formula (I) is therefore the mixture of the compound of formula (Ia) with a compound of formula (Ib),

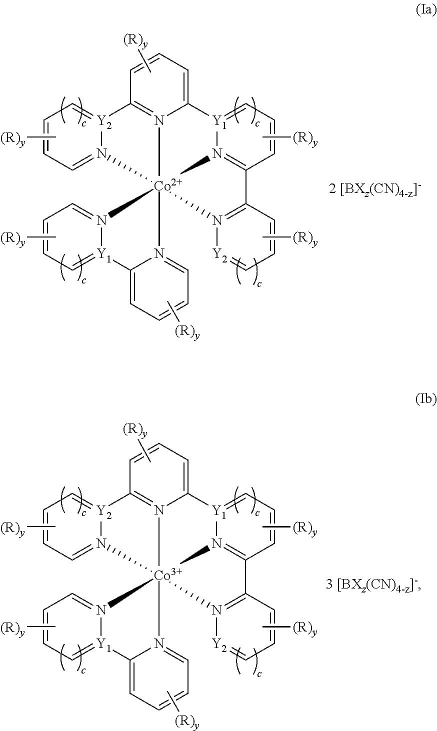

in which

the substituents Y₁, Y₂, c, X, z, R and y are identical or different and are defined as:

Y₁ and Y₂ are each independently C or N,

c is 0 in the case Y₁ and/or Y₂ are N,

c is 1 in the case Y₁ and/or Y₂ are C,

X is H or F,

z is 1 or 2,

y is each independently 0, 1, 2, 3 or 4,

R is each independently a straight-chain or branched alkyl group with 1 to 20 C atoms.

Compounds of formula (Ia) and (Ib) are defined in such a way that the given formulae comprise all possible stereoisomeric forms.

In one embodiment of the invention, it is preferred that the substituents X and z in the Co^{II}/Co^{III}-redox couple of formula (I) are identical thus forming Co^{II}/Co^{III}-redox couples of formula (IA), Co^{II}/Co^{III}-redox couples of formula (IB), Co^{II}/Co^{III}-redox couples of formula (IC) and Co^{II}/Co^{III}-redox couples of formula (ID).

A Co^{II}/Co^{III}-redox couple of formula (IA) is the Co^{II}/Co^{III}-redox couple of formula (I) in which X is H and z is 1 thus building the anion [BH(CN)₃]⁻ in formula (Ia) and (Ib), wherein the substituents Y₁, Y₂, c, R and y are identical or different and are defined as described above.

A Co^{II}/Co^{III}-redox couple of formula (IB) is the Co^{II}/Co^{III}-redox couple of formula (I) in which X is H and z is 2 thus building the anion [BH₂(CN)₂]⁻ in formula (Ia) and (Ib), wherein the substituents Y₁, Y₂, c, R and y are identical or different and are defined as described above.

A Co^{II}/Co^{III}-redox couple of formula (IC) is the Co^{II}/Co^{III}-redox couple of formula (I) in which X is F and z is 1 thus building the anion [BF(CN)₃]⁻ in formula (Ia) and (Ib), wherein the substituents Y₁, Y₂, c, R and y are identical or different and are defined as described above.

A Co^{II}/Co^{III}-redox couple of formula (ID) is the Co^{II}/Co^{III}-redox couple of formula (I) in which X is F and z is 2 thus building the anion [BF₂(CN)₂]⁻ in formula (Ia) and (Ib), wherein the substituents Y₁, Y₂, c, R and y are identical or different and are defined as described above.

In one embodiment of the invention, preferred compounds of formula (I), as described above, are compounds in which z is 1 corresponding to compounds of formula (IA) and (IC), wherein Y₁, Y₂, c, R, y and n have a meaning as described above or below.

In one embodiment of the invention, preferred Co^{II}/Co^{III}-redox couples of formula (I) are therefore Co^{II}/Co^{III}-redox couples of formula (IA) and (IC), wherein Y₁, Y₂, c, R and y have a meaning as described above or below.

In another embodiment of the invention, preferred compounds of formula (I), as described above, are compounds in which z is 2 corresponding to compounds of formula (IB) and (ID), wherein Y₁, Y₂, c, R, y and n have a meaning as described above or below.

In one embodiment of the invention, preferred Co^{II}/Co^{III}-redox couples of formula (I) are therefore Co^{II}/Co^{III}-redox couples of formula (IB) and (ID), wherein Y₁, Y₂, c, R and y have a meaning as described above or below.

In another embodiment of the invention, preferred compounds of formula (I), as described above, are compounds in which X is H corresponding to compounds of formula (IA) and (IB), wherein Y₁, Y₂, c, R, y and n have a meaning as described above or below.

In one embodiment of the invention, preferred Co^{II}/Co^{III}-redox couples of formula (I) are therefore Co^{II}/Co^{III}-redox couples of formula (IA) and (IB), wherein Y₁, Y₂, c, R and y have a meaning as described above or below.

In another embodiment of the invention, preferred compounds of formula (I), as described above, are compounds in which X is F corresponding to compounds of formula (IC) and (ID), wherein Y₁, Y₂, c, R, y and n have a meaning as described above or below.

In one embodiment of the invention, preferred Co^{II}/Co^{III}-redox couples of formula (I) are therefore Co^{II}/Co^{III}-redox couples of formula (IC) and (ID), wherein Y₁, Y₂, c, R and y have a meaning as described above or below.

Compounds of formula (IA), wherein Y₁, Y₂, c, R, y and n have a meaning as described above or below, are particularly preferred compounds of formula (I).

Co^{II}/Co^{III}-redox couples of formula (IA), wherein Y₁, Y₂, c, R and y have a meaning as described above or below, are particularly preferred Co^{II}/Co^{III}-redox couples of formula (I).

In one embodiment of the invention, compounds of formula (I), (IA), (IB), (IC), (ID) are preferred in which Y₂ is two times C and the adjacent substituents c are 1 and Y₁ is two times N and the adjacent substituents c are 0.

Compounds of formula (I) in which Y₂ is two times C and the adjacent substituents c are 1 and Y₁ is two times N and the adjacent substituents c are 0 are therefore compounds of formula (I-1), where X, z, R, y and n have a meaning as described above or below:

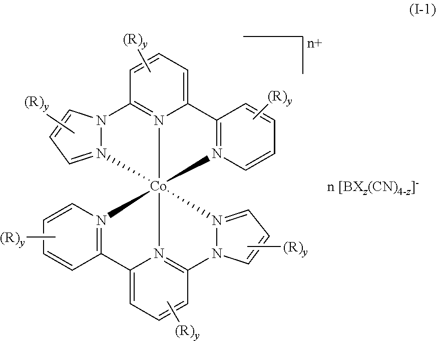

Compounds of formula (I-1A) are compounds of formula (I-1), in which X is H and z is 1:

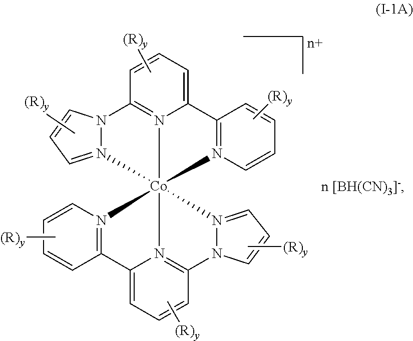

wherein R, y and n have a meaning as described above or below.

Compounds of formula (I-1B) are compounds of formula (I-1), in which X is H and z is 2:

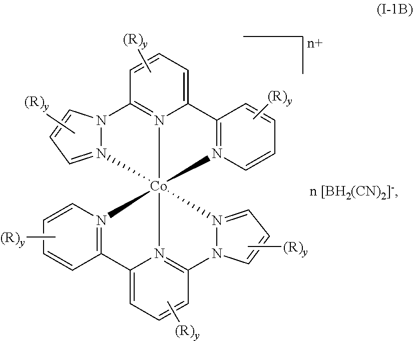

wherein R, y and n have a meaning as described above or below.

Compounds of formula (I-1C) are compounds of formula (I-1), in which X is F and z is 1:

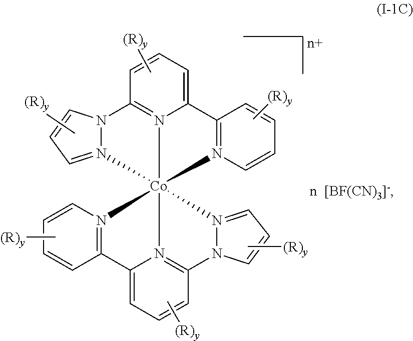

wherein R, y and n have a meaning as described above or below.

Compounds of formula (I-1D) are compounds of formula (I-1), in which X is F and z is 2:

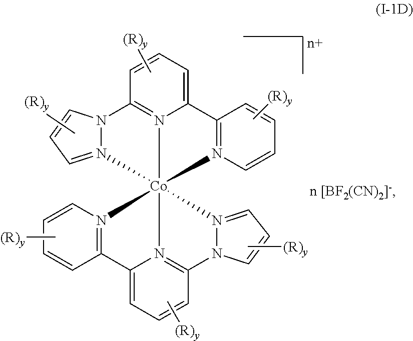

wherein R, y and n have a meaning as described above or below.

Compounds of formula (I-1), (I-1A), (I-1B), (I-1C), (I-1D) are defined in such a way that the given formulae comprise all possible stereoisomeric forms.

The invention furthermore relates to the use of at least one compound of formula (I-1), (I-1A), (I-1B), (I-1C) or (I-1D) as redox active species.

In another embodiment of the invention, compounds of formula (I), (IA), (IB), (IC), (ID) are preferred in which Y₁ and Y₂ are C and the adjacent substituents c are 1.

Compounds of formula (I) in which in which Y₁ and Y₂ are C and the adjacent substituents c are 1 are therefore compounds of formula (I-2), where X, z, R, y and n have a meaning as described above or below:

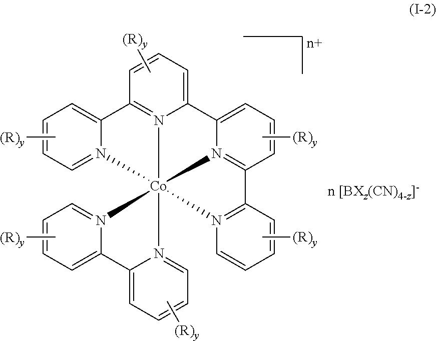

Compounds of formula (I-2A) are compounds of formula (I-2), in which X is H and z is 1:

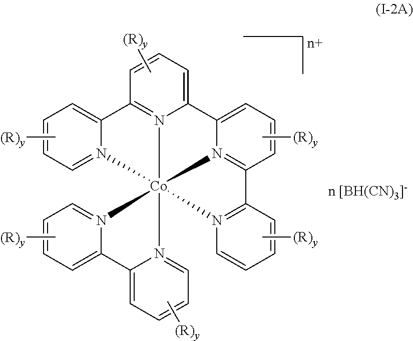

wherein R, y and n have a meaning as described above or below.

Compounds of formula (I-2B) are compounds of formula (I-2), in which X is H and z is 2:

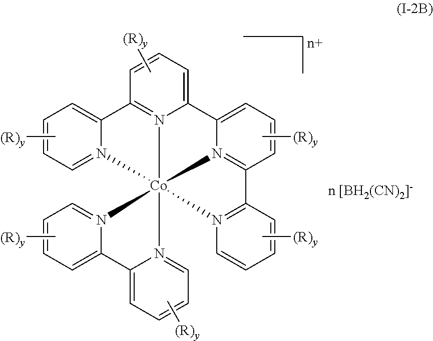

wherein R, y and n have a meaning as described above or below.

Compounds of formula (I-2C) are compounds of formula (I-2), in which X is F and z is 1:

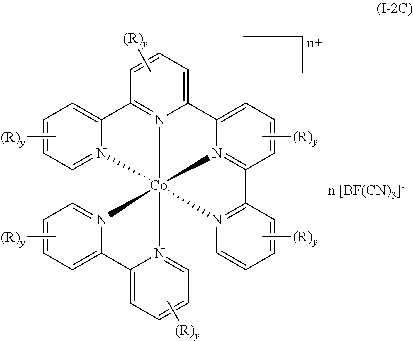

wherein R, y and n have a meaning as described above or below.

Compounds of formula (I-2D) are compounds of formula (I-2), in which X is F and z is 2:

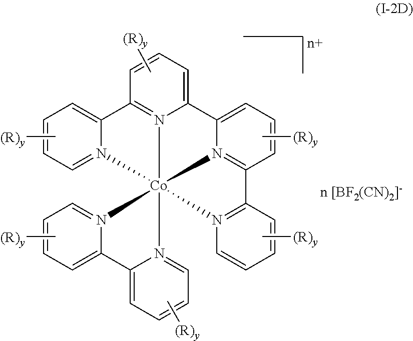

wherein R, y and n have a meaning as described above or below.

Compounds of formula (I-2), (I-2A), (I-2B), (I-2C), (I-2D) are defined in such a way that the given formulae comprise all possible stereoisomeric forms.

The invention furthermore relates to the use of at least one compound of formula (I-2), (I-2A), (I-2B), (I-2C) or (I-2D) as redox active species.

In another embodiment of the invention, compounds of formula (I), (IA), (IB), (IC), (ID) are preferred in which Y₁ and Y₂ are N and the adjacent substituents c are 0.

Compounds of formula (I) in which in which Y₁ and Y₂ are N and the adjacent substituents c are 0 are therefore compounds of formula (I-3), where X, z, R, y and n have a meaning as described above or below:

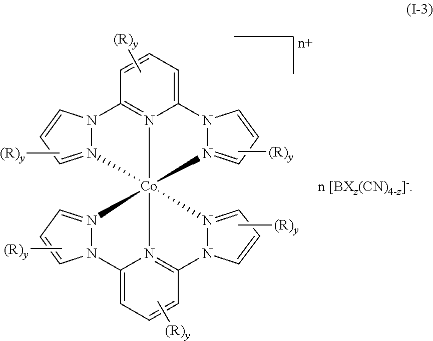

Compounds of formula (I-3A) are compounds of formula (I-3), in which X is H and z is 1:

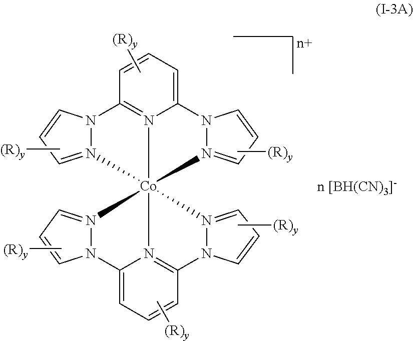

wherein R, y and n have a meaning as described above or below.

Compounds of formula (I-3B) are compounds of formula (I-3), in which X is H and z is 2:

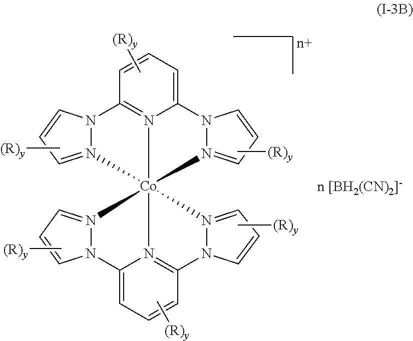

wherein R, y and n have a meaning as described above or below.

Compounds of formula (I-3C) are compounds of formula (I-3), in which X is F and z is 1:

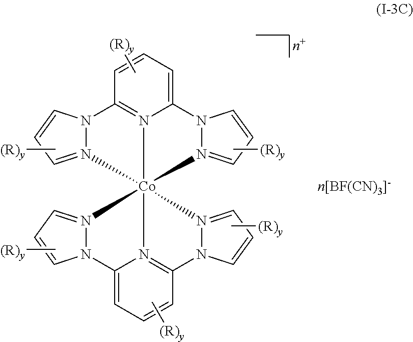

wherein R, y and n have a meaning as described above or below.

Compounds of formula (I-3D) are compounds of formula (I-3), in which X is F and z is 2:

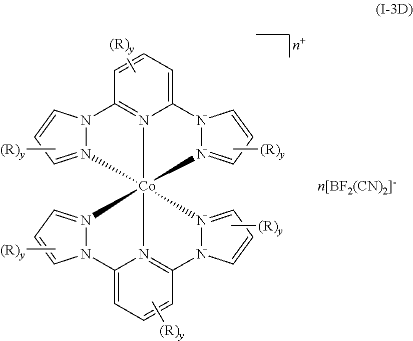

wherein R, y and n have a meaning as described above or below.

Compounds of formula (I-3), (I-3A), (I-3B), (I-3C), (I-3D) are defined in such a way that the given formulae comprise all possible stereoisomeric forms.

The invention furthermore relates to the use of at least one compound of formula (I-3), (I-3A), (I-3B), (I-3C) or (I-3D) as redox active species.

R in compounds of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) and (I-3D), or in Co^{II}/Co^{III}-redox couples of formula (I), (IA), (IB), (IC), (ID) (I-1), (I-1A), (I-1B), (I-1C), (I-1D), (I-2), (I-2A), (I-2B), (I-2C), (I-2D), (I-3), (I-3A), (I-3B), (I-3C) and (I-3D) each independently denotes preferably a straight-chain or branched alkyl group with 1 to 10 C atoms.

R in compounds of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) and (I-3D) each independently denotes particularly preferably methyl, ethyl, isopropyl, n-butyl, sec.-butyl or tert.-butyl.

R in compounds of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) and (I-3D) each independently denotes very particularly preferably methyl or tert.-butyl.

Compounds of formula (I), (IA), (IB), (IC), (ID), (I-1), (I-1A), (I-1B), (I-1C), (I-1 D), (I-2), (I-2A), (I-2B), (I-2C), (I-2D), (I-3), (I-3A), (I-3B), (I-3C) and (I-3D) are preferred in which y is each independently 0 or 1. In case y is 1, Y₁ and/or Y₂ are C and r is 1, each substituent R is independently preferably in meta- or para-position to the N-atom of the pyridine ring. In case y is 1, Y₁ and/or Y₂ are C and r is 1, each substituent R is particularly preferably in para-position to the N-atom of the pyridine ring.

Co^{II}/Co^{III}-redox couples of formula (I), (IA), (IB), (IC), (ID), (I-1), (I-1A), (I-1 B), (I-1C), (I-1D), (I-2), (I-2A), (I-2B), (I-2C), (I-2D), (I-3), (I-3A), (I-3B), (I-3C) and (I-3D) are therefore preferred in which y is 0 or 1. In case y is 1 and Y₁ and/or Y₂ are C and r is 1, each substituent R is independently preferably in meta- or para-position to the N-atom of the pyridine ring. In case y is 1, Y₁ and/or Y₂ are C and r is 1, each substituent R is particularly preferably in para-position to the N-atom of the pyridine ring.

In case y is 1, Y₁ and/or Y₂ are N and r is 0, each substituent R is independently preferably in position 3 to one of the N-atoms of the pyrazole ring.

Co^{II}/Co^{III}-redox couples of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) and (I-3D) are therefore preferred in which y is 0 or 1. In case y is 1 and Y₁ and/or Y₂ are N and r is 0, each substituent R is independently preferably in position 3 to one of the N-atoms of the pyrazole ring.

Compounds of formula (I), (IA), (IB), (IC), (ID), (I-1), (I-1A), (I-1B), (I-1C), (I-ID), (I-2), (I-2A), (I-2B), (I-2C), (I-2D), (I-3), (I-3A), (I-3B), (I-3C) and (I-3D) are particularly preferred in which y is two times 1 and four times 0 or four times 1 and two times 0.

Co^{II}/Co^{III}-redox couples of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) and (I-3D) are therefore particularly preferred in which y is two times 1 and four times 0 or four times 1 and two times 0.

It is preferred that y is 0 in case of Y₁ and/or Y₂ are N and c is 0 and that y is 1 in case of Y₁ and/or Y₂ are C and c is 1.

Compounds of formula (I), (IA), (IB), (IC), (ID), (I-1), (I-1A), (I-1B), (I-1C), (I-ID), (I-2), (I-2A), (I-2B), (I-2C), (I-2D), (I-3), (I-3A), (I-3B), (I-3C) and (I-3D) are very particularly preferred in which y is 0.

Co^{II}/Co^{III}-redox couples of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) and (I-3D) are therefore very particularly preferred in which y is 0.

Examples of compounds of formula (I) are the following compounds:

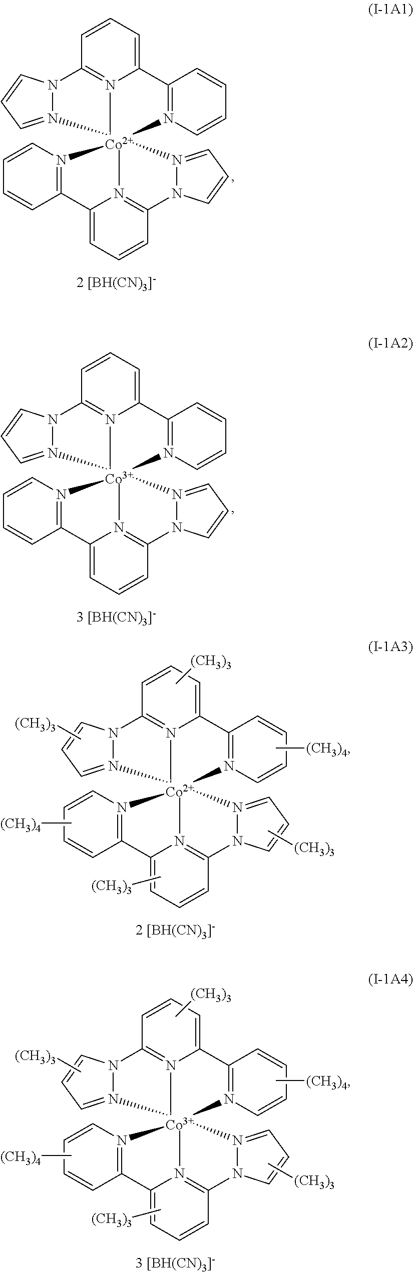

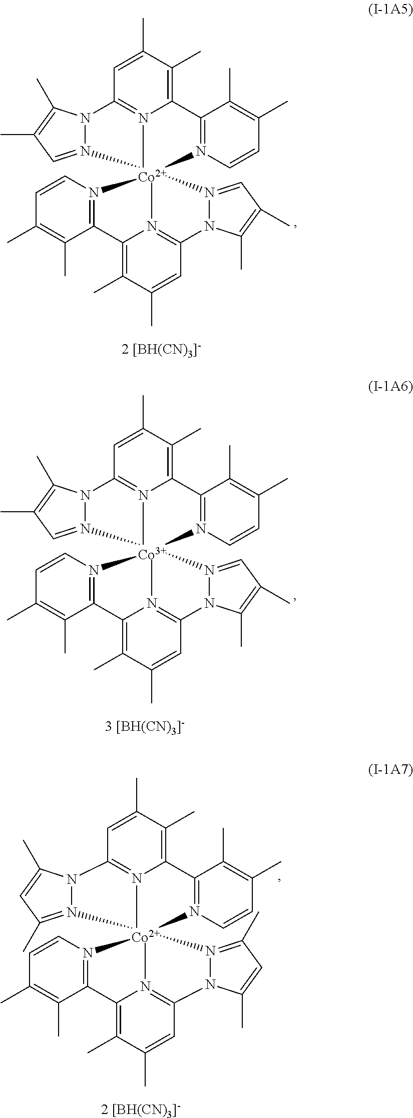

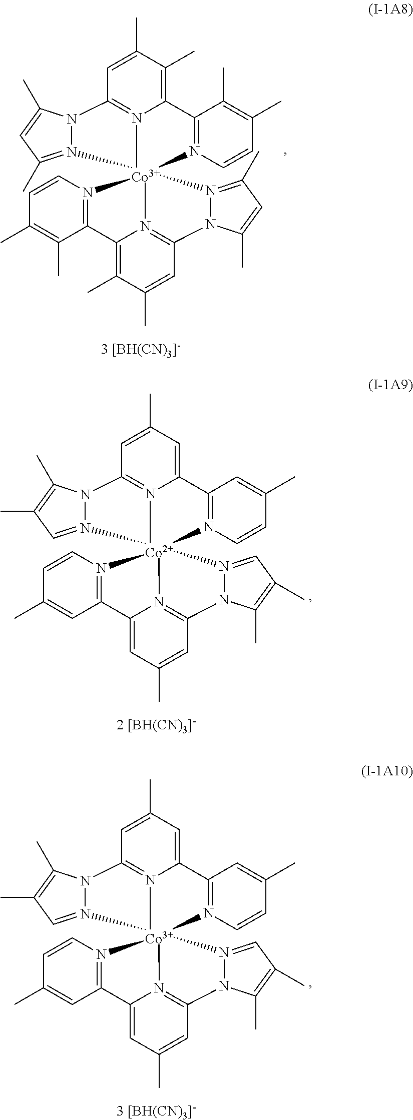

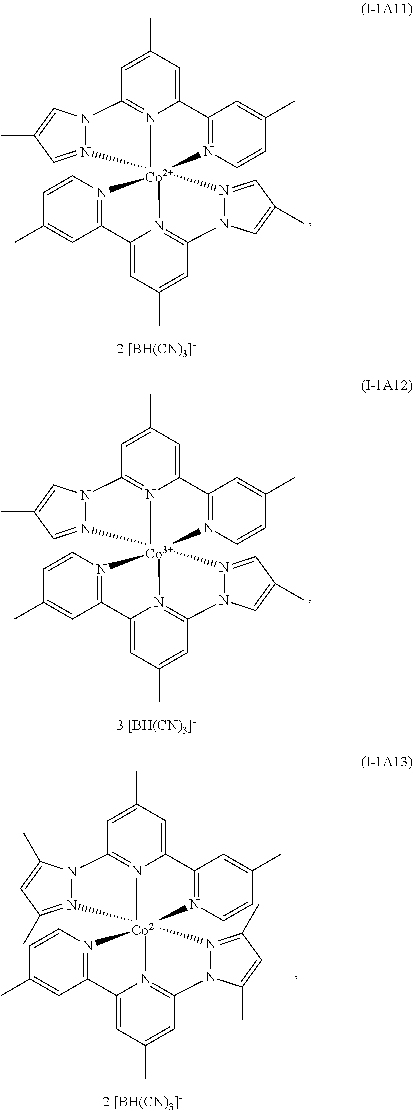

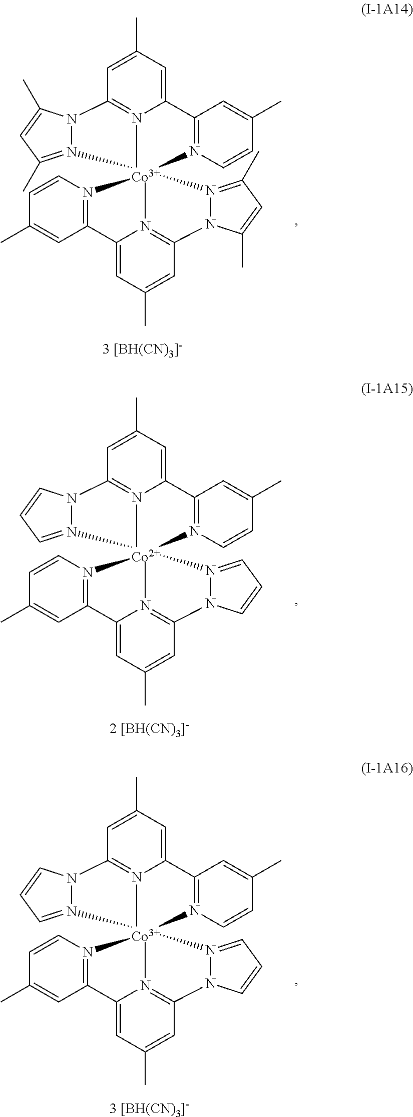

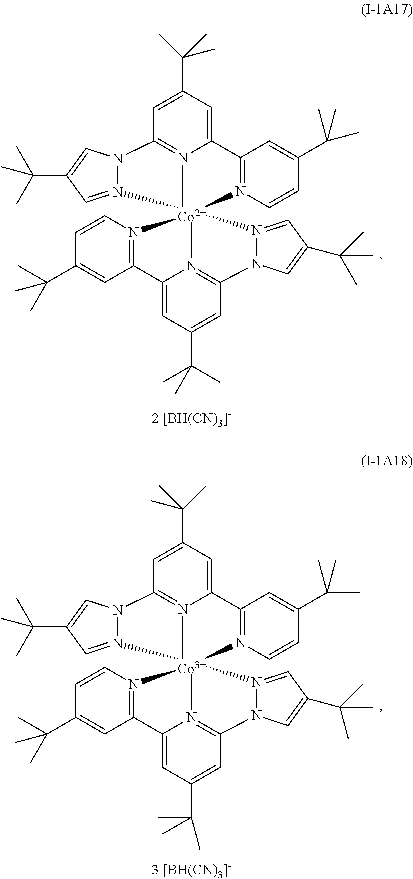

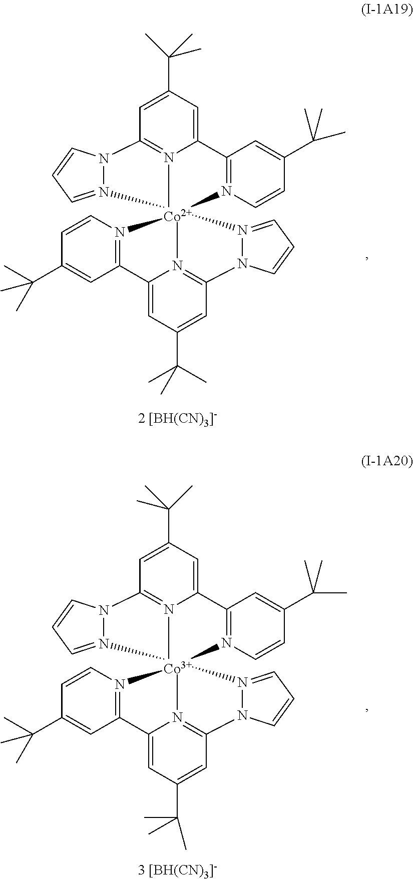

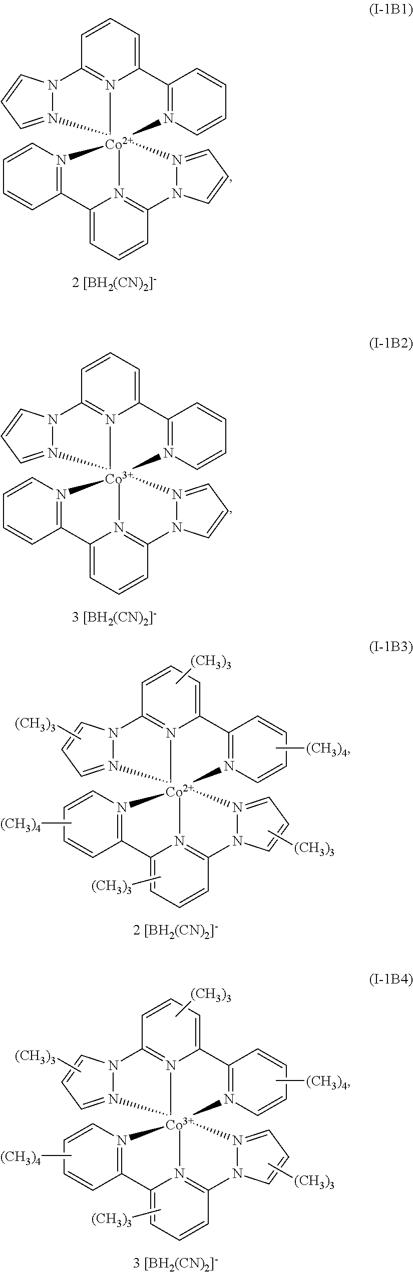

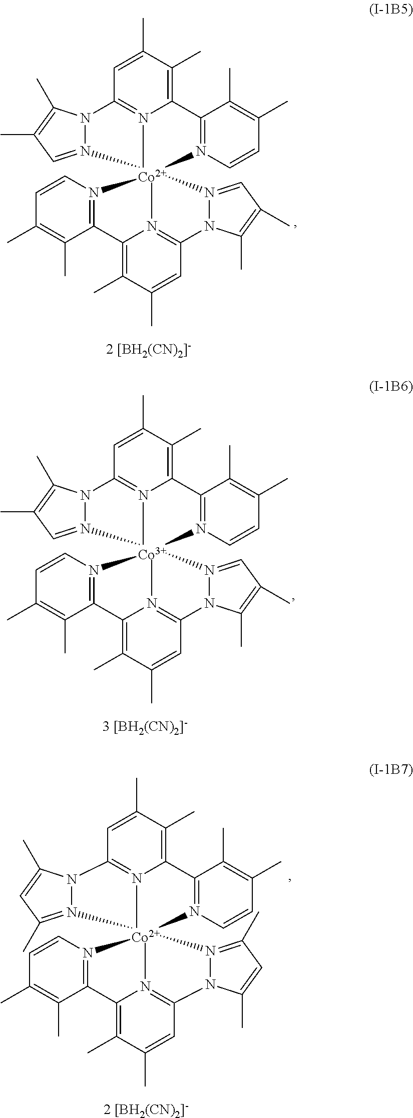

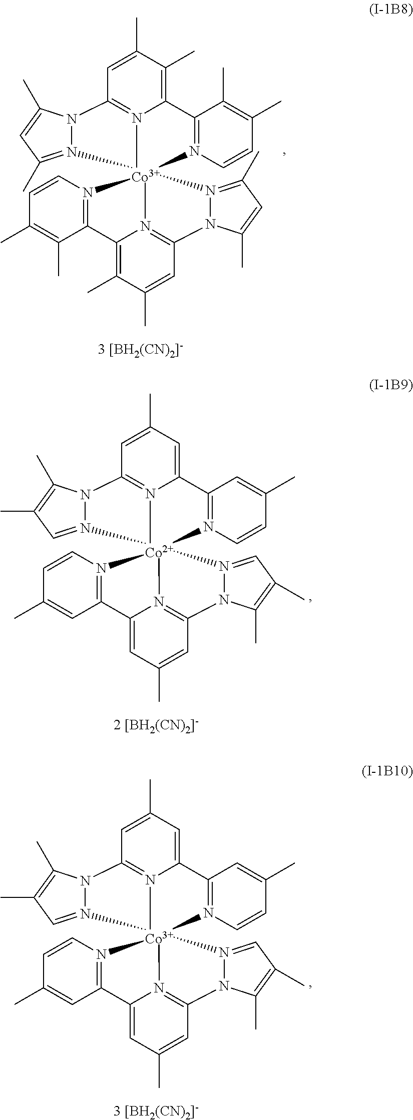

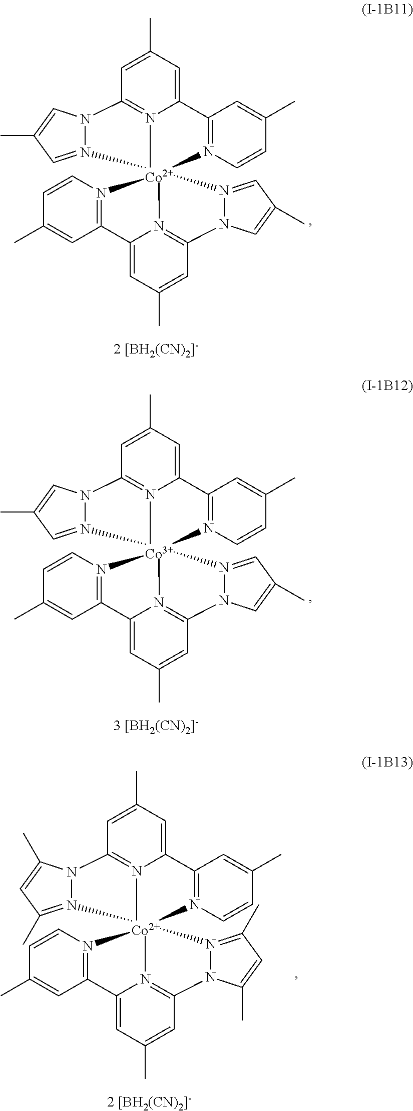

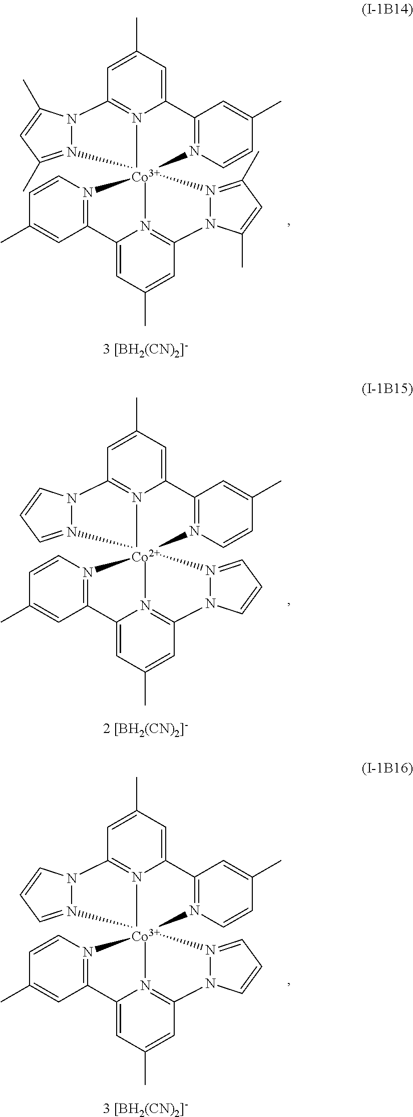

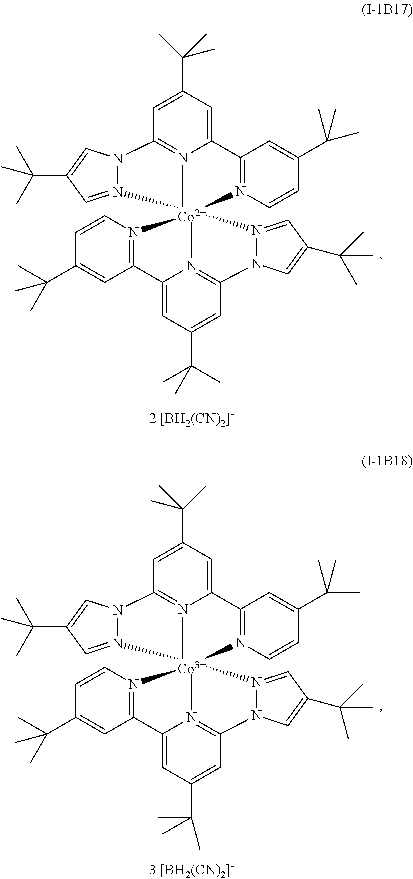

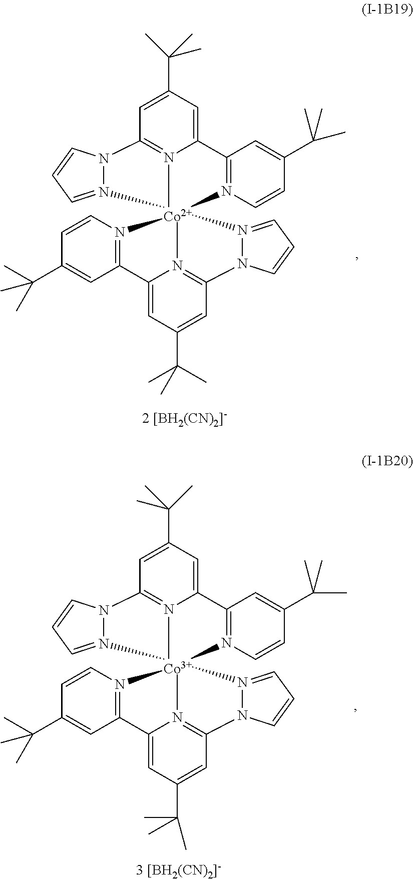

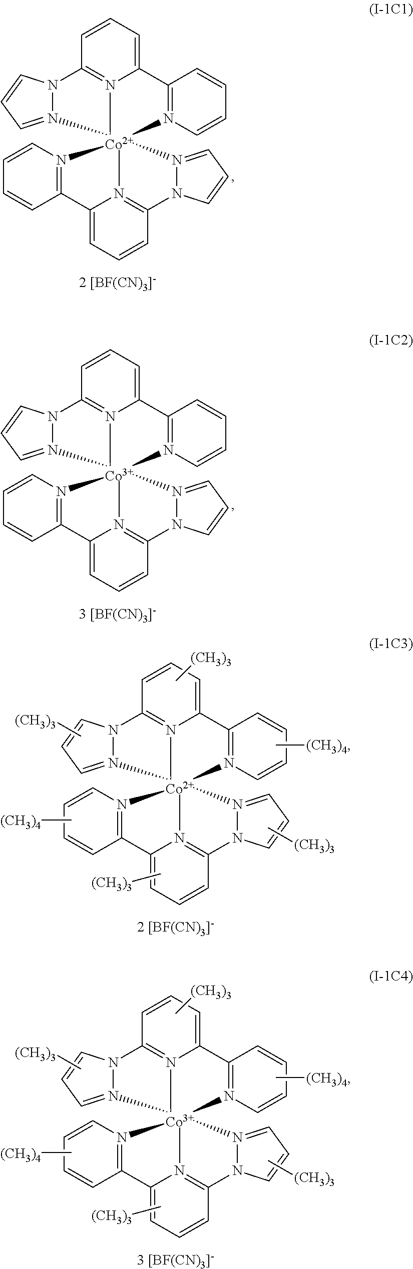

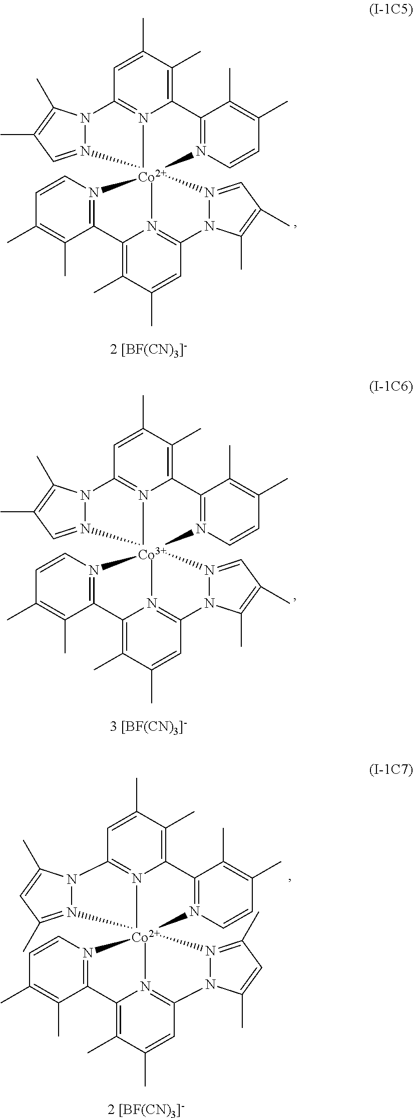

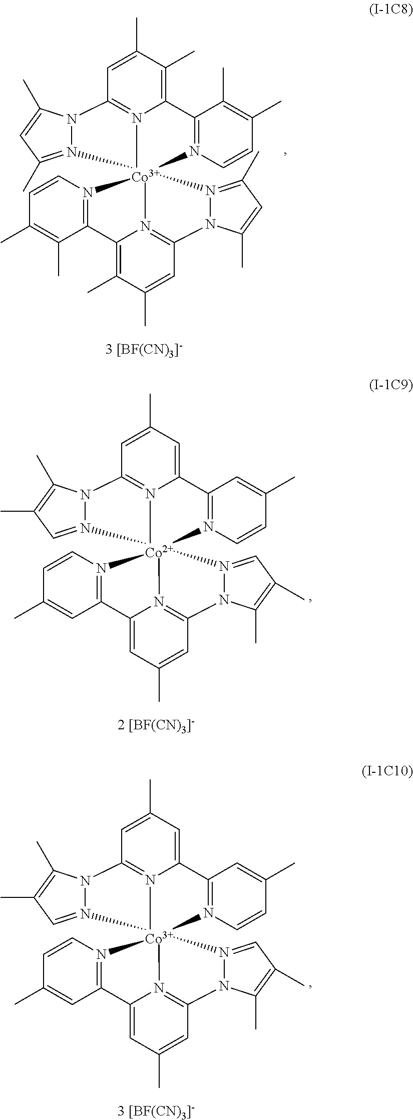

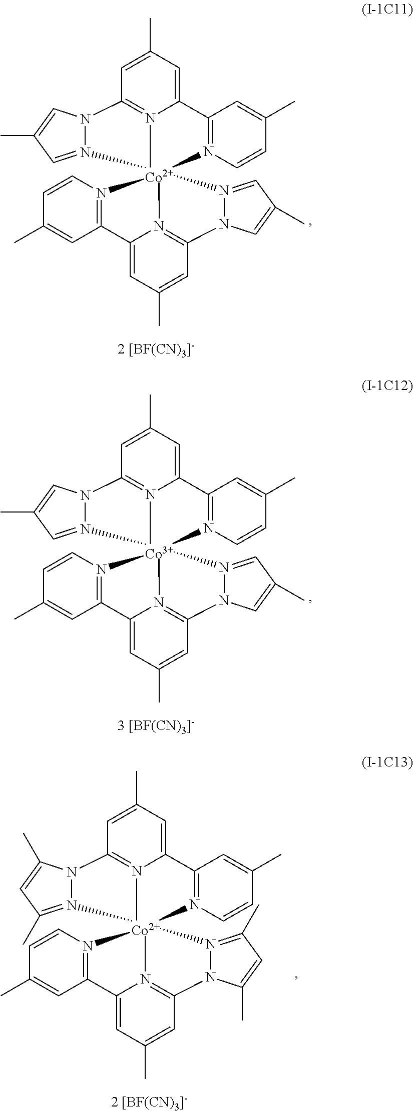

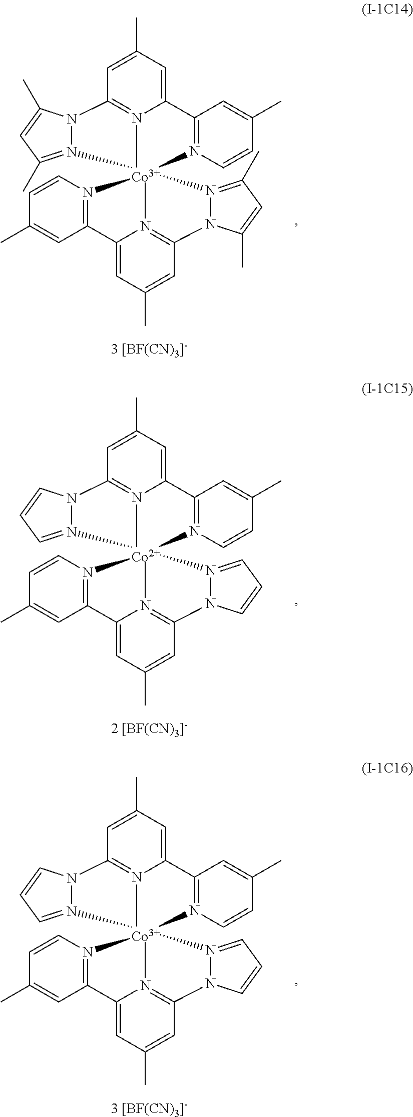

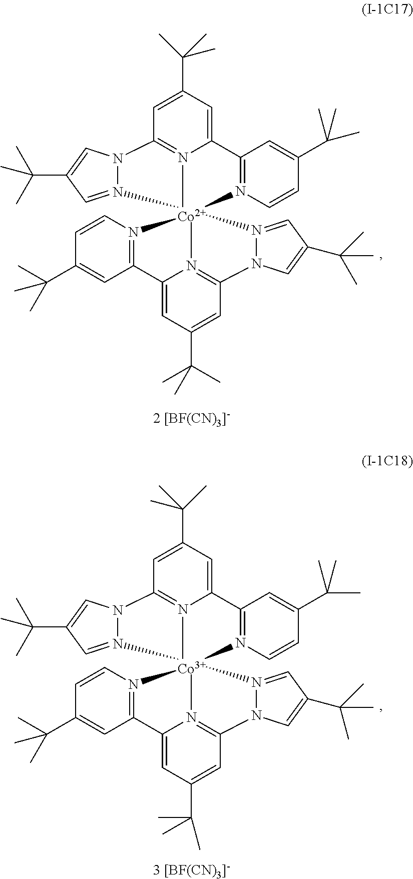

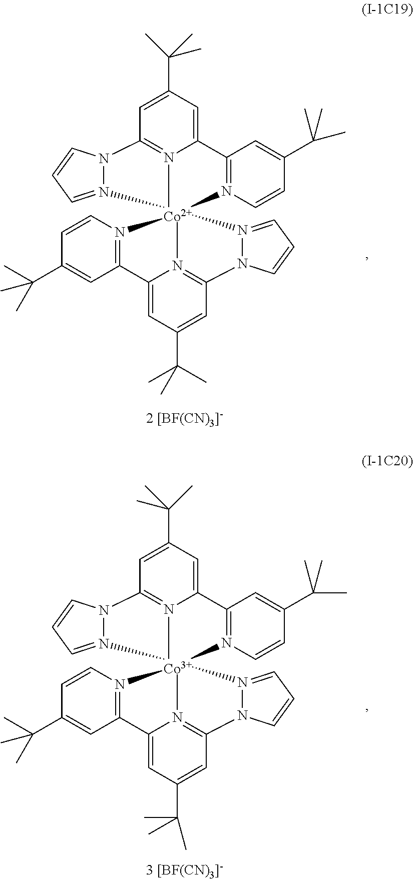

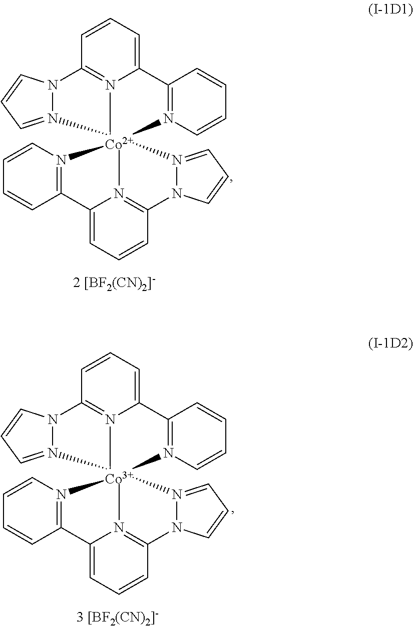

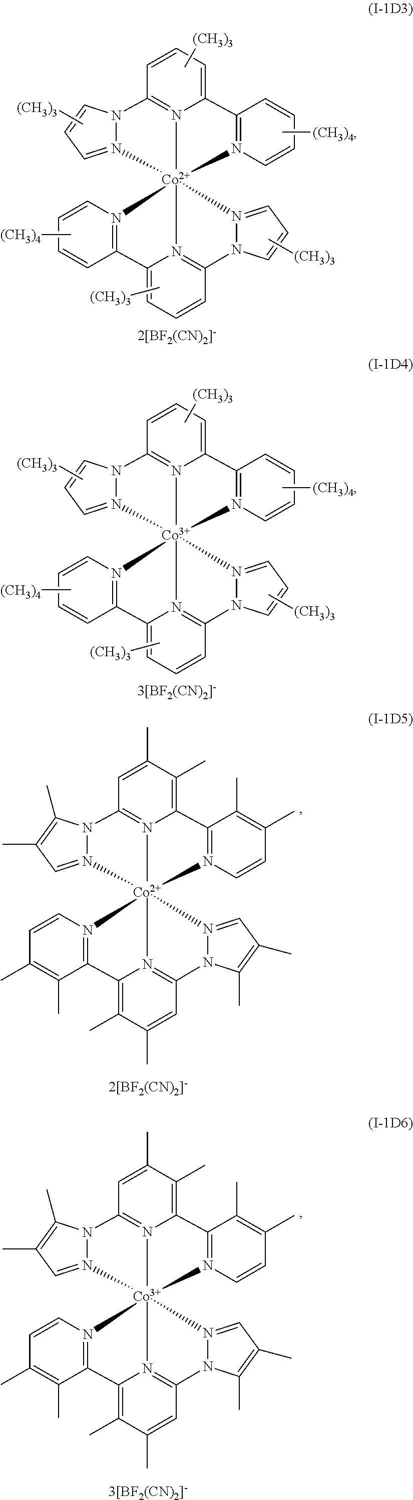

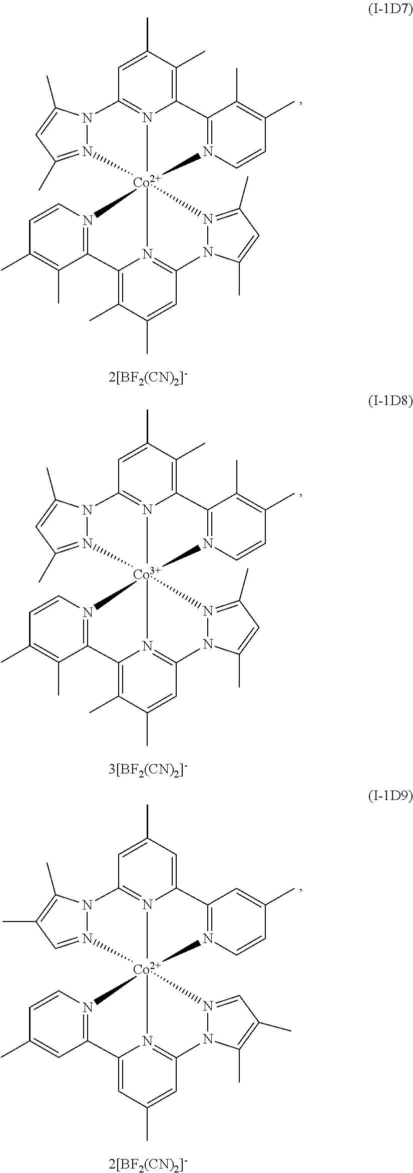

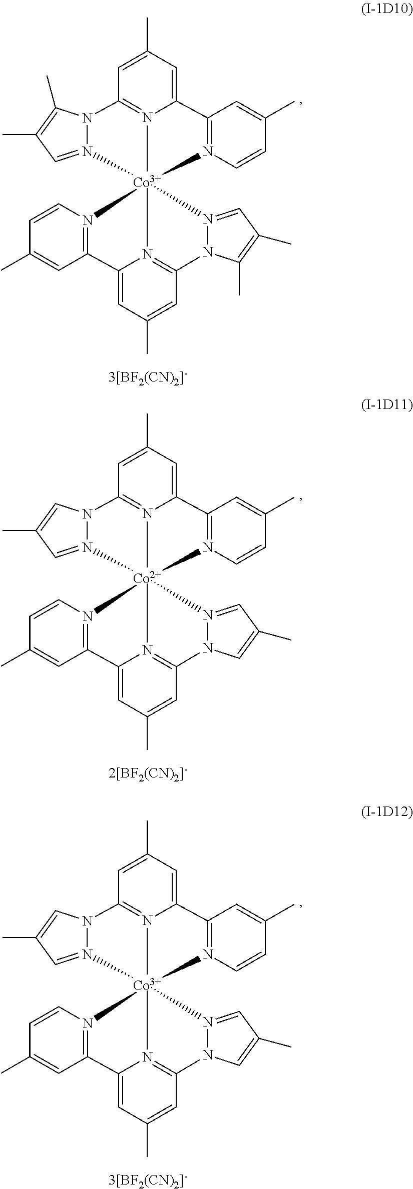

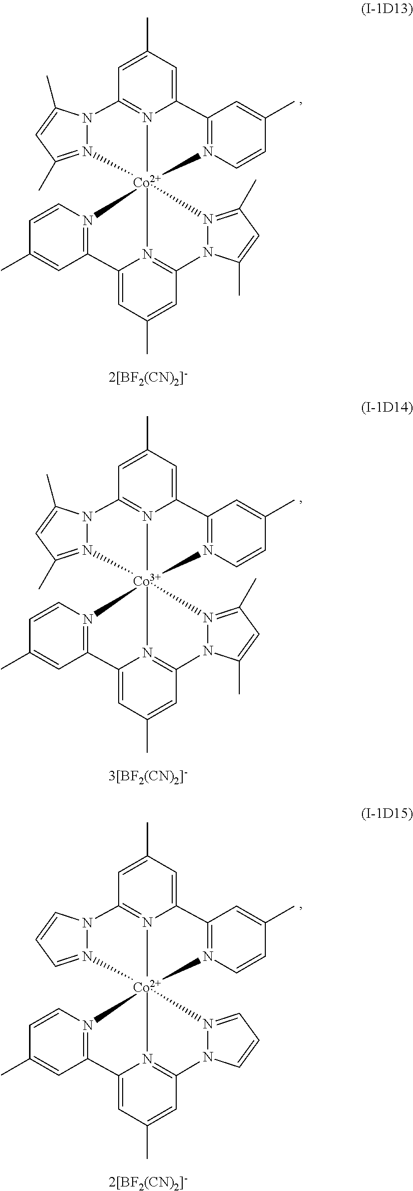

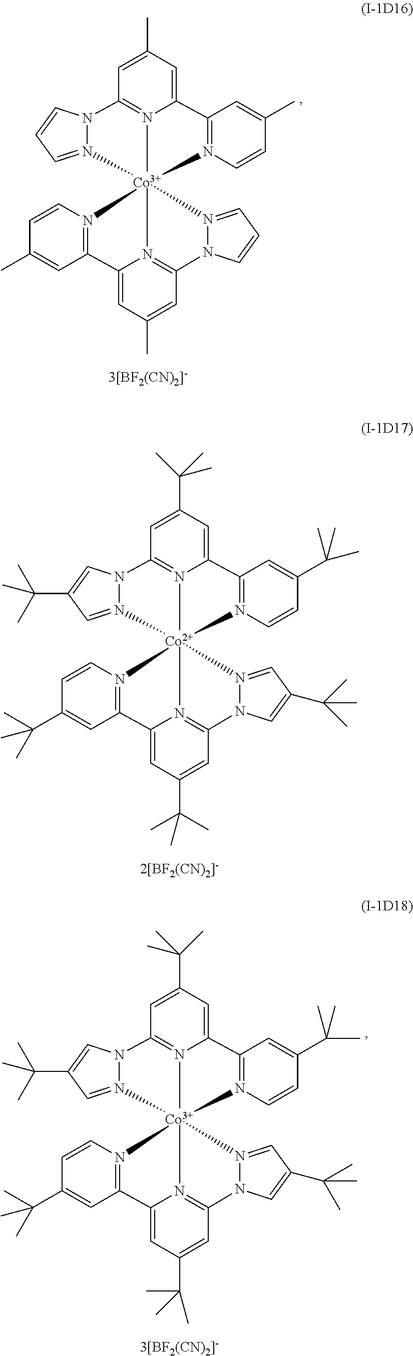

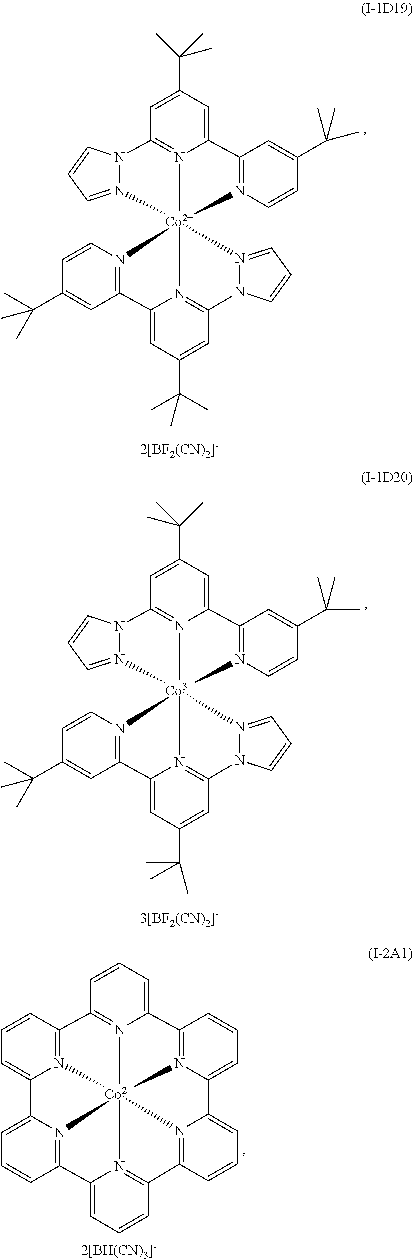

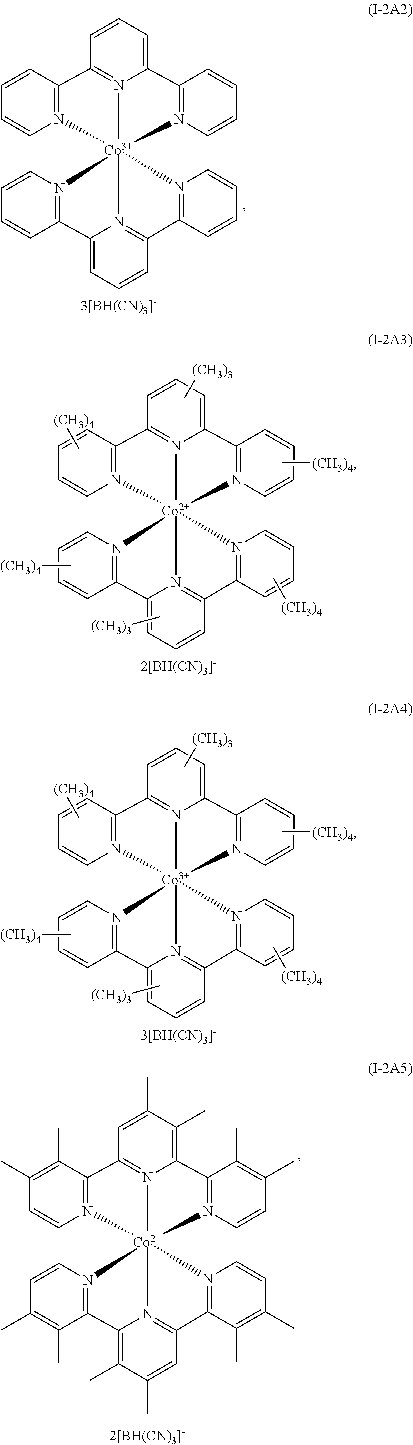

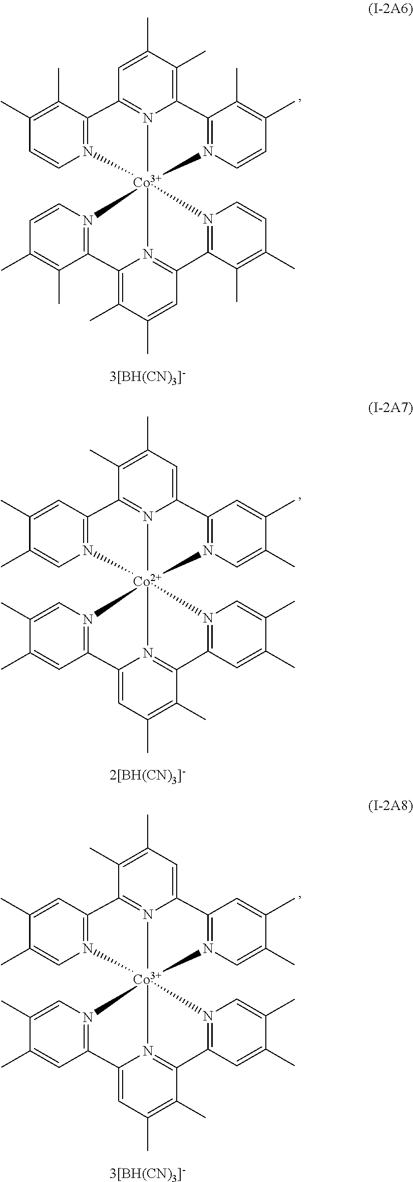

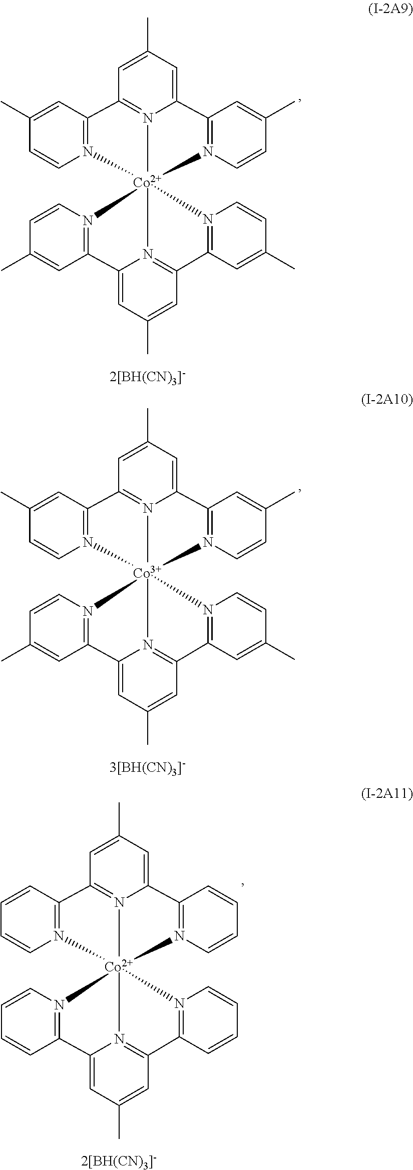

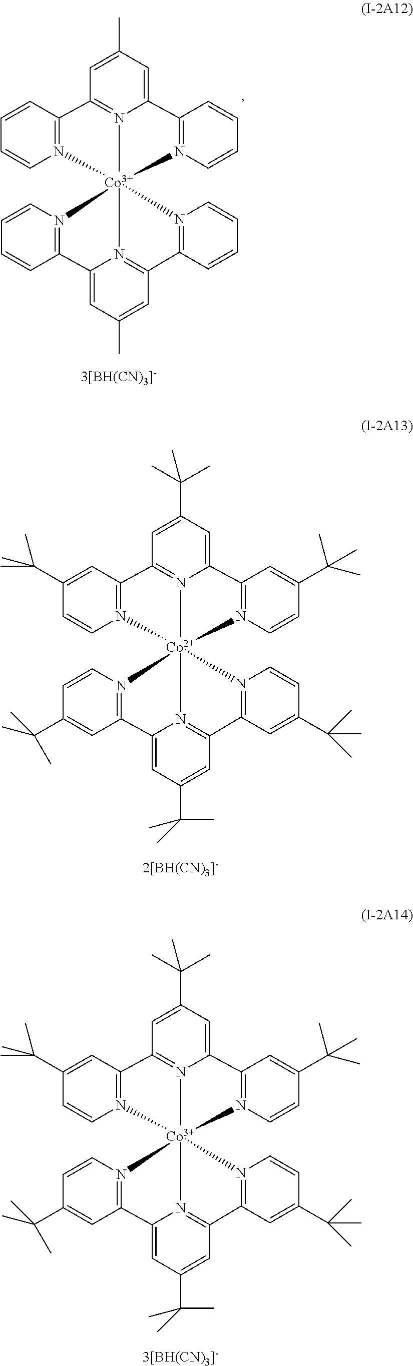

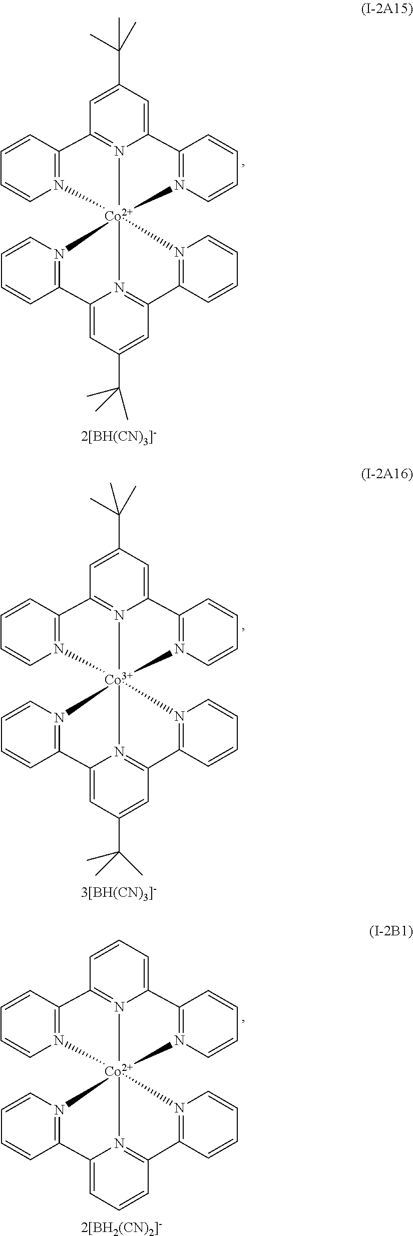

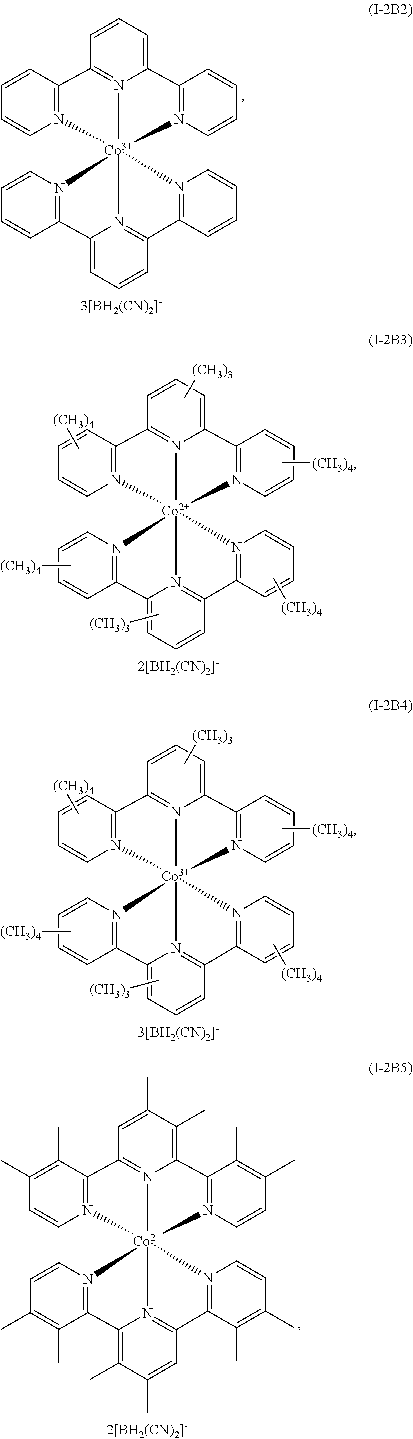

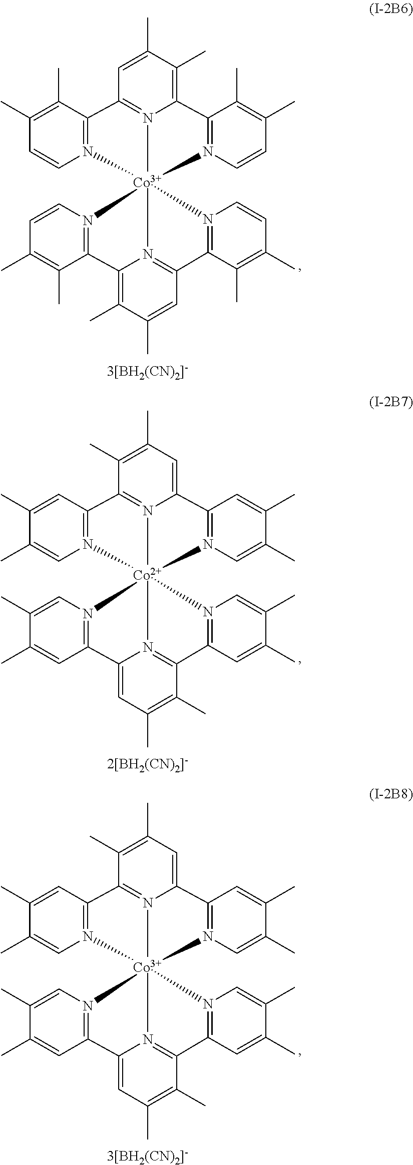

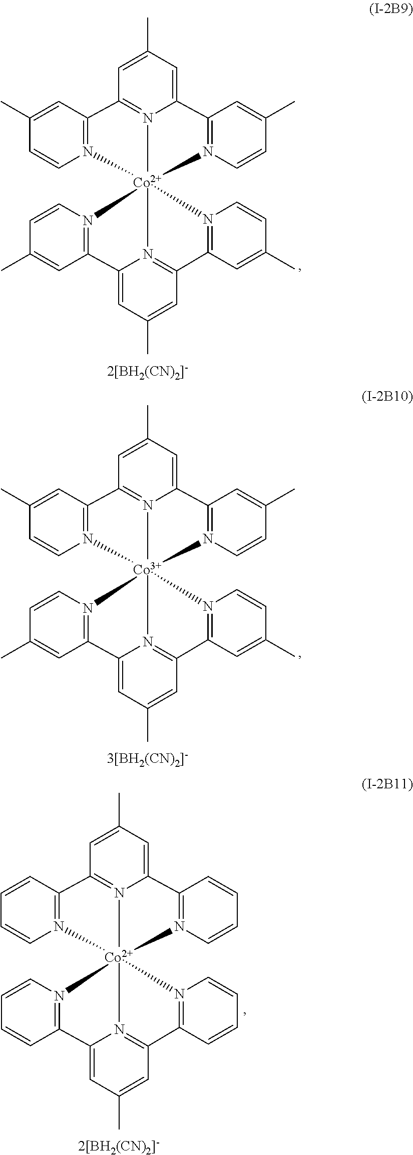

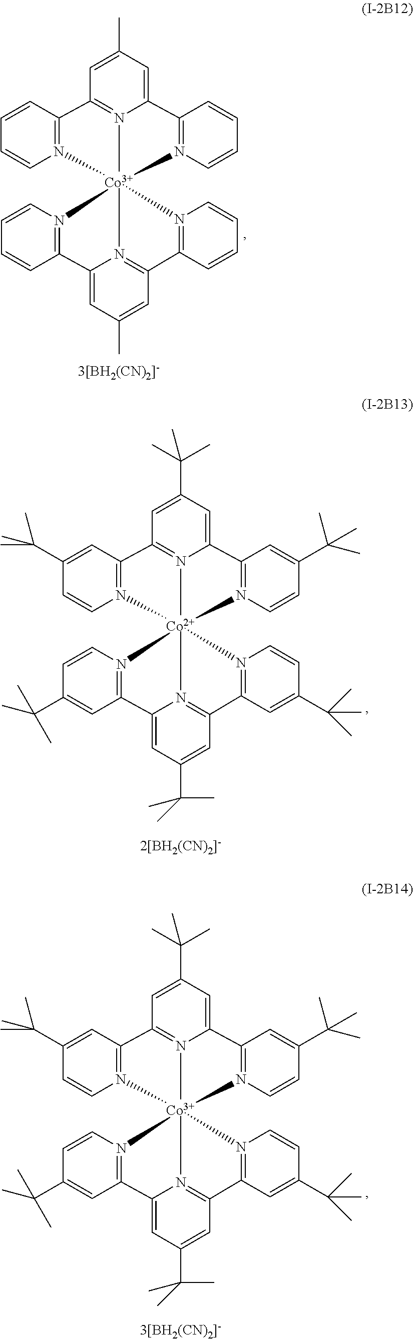

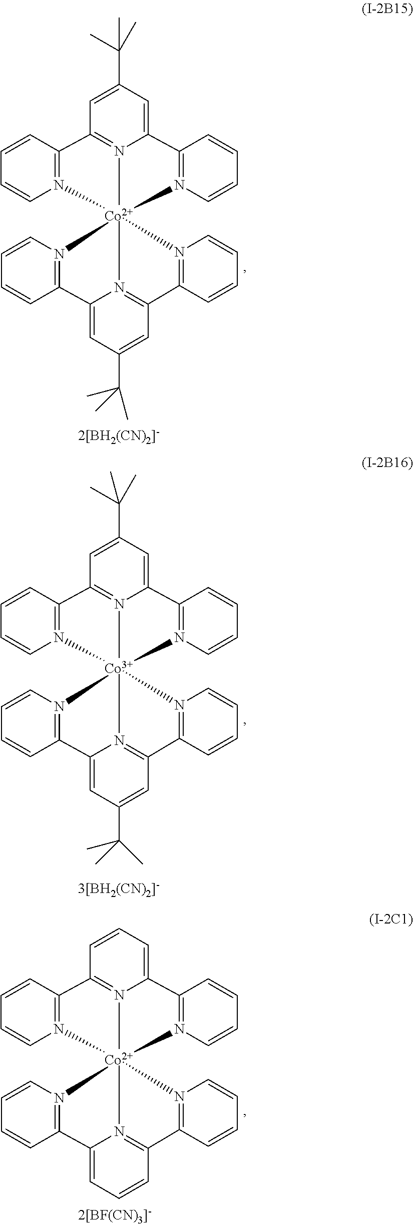

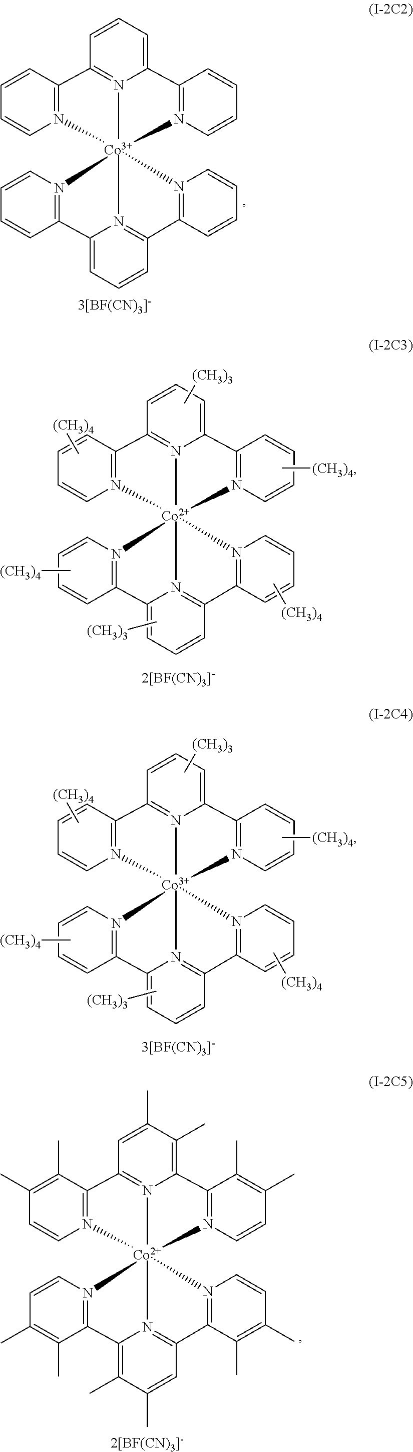

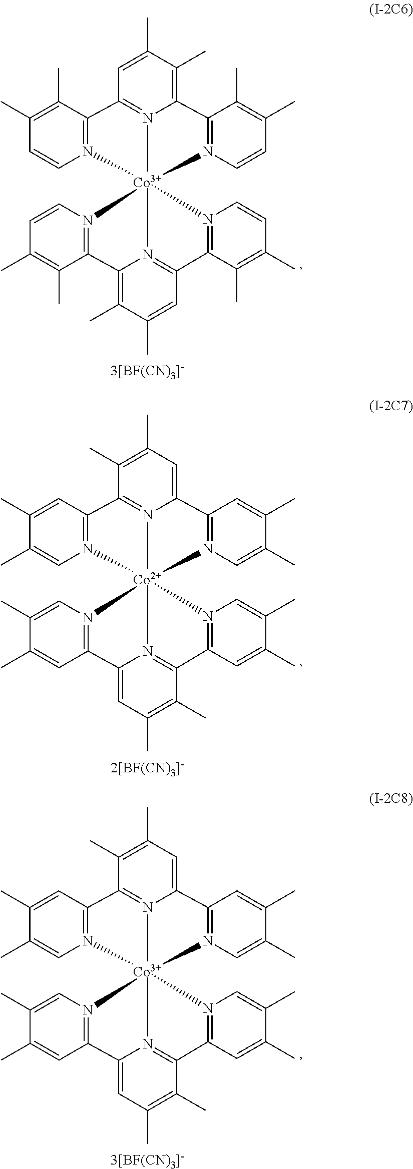

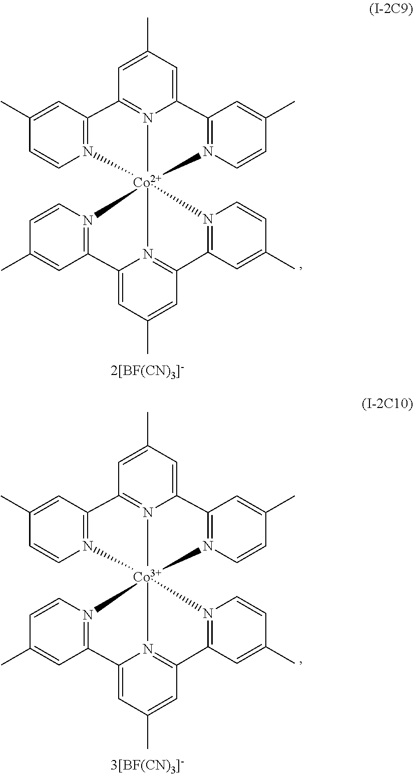

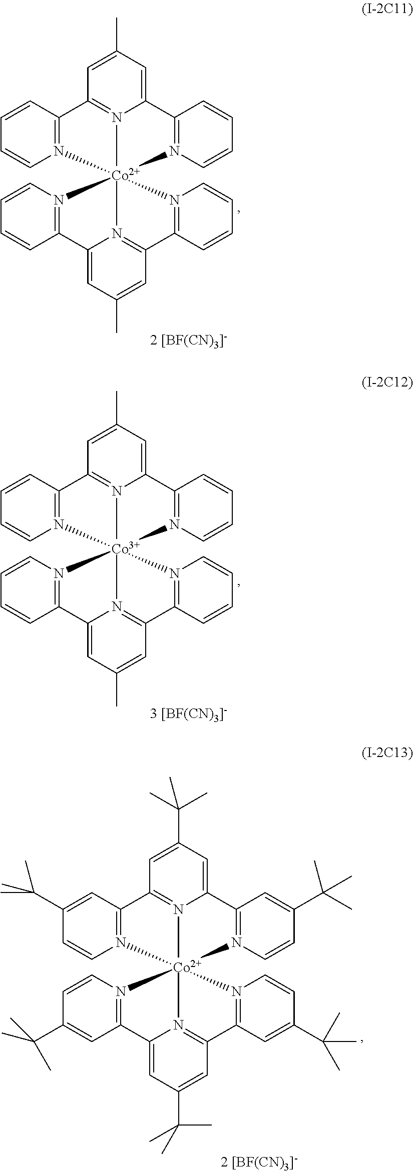

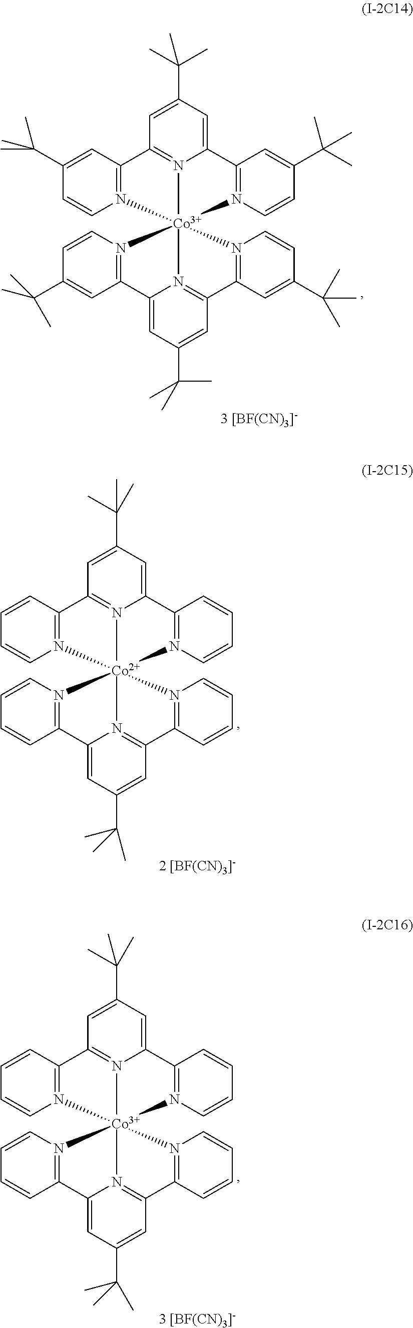

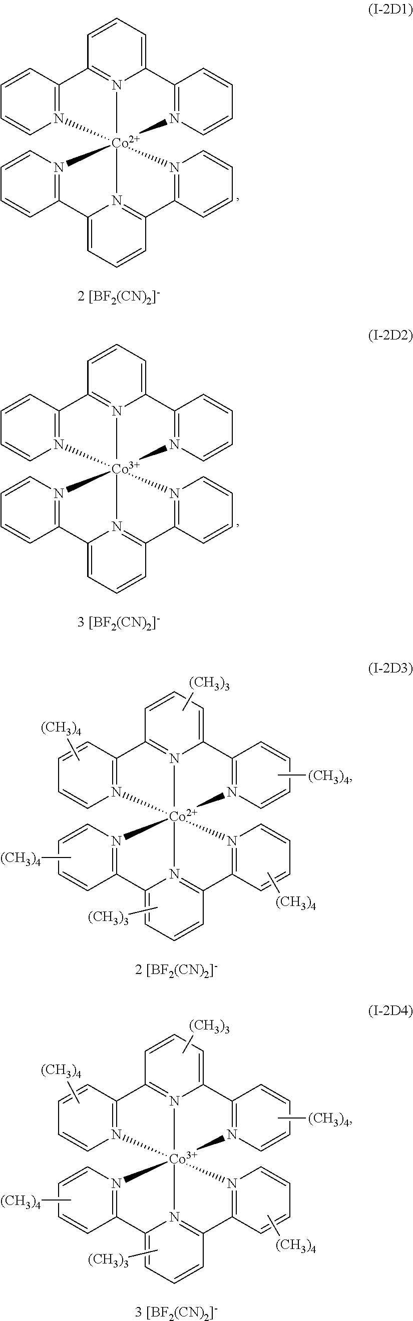

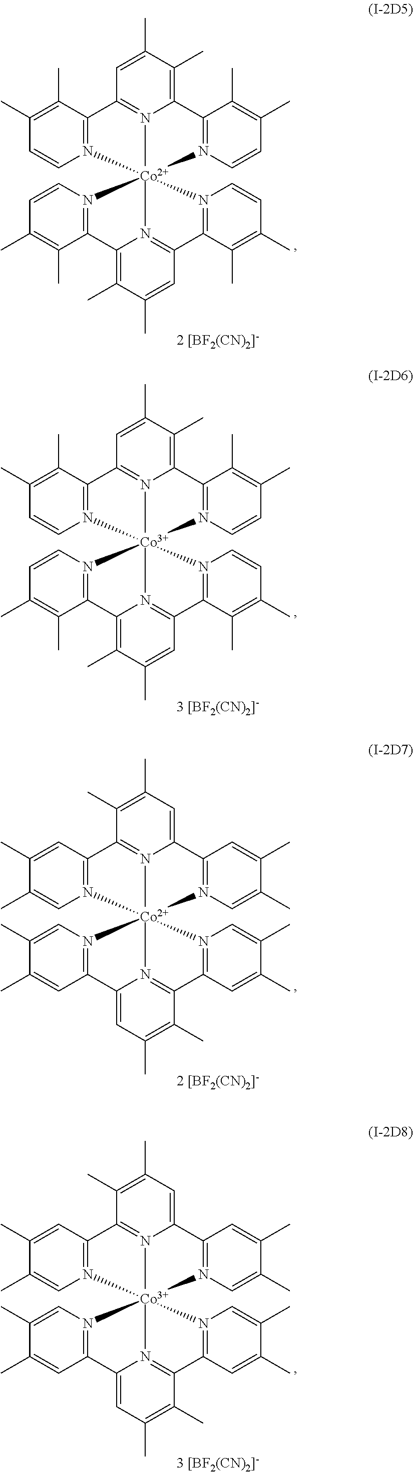

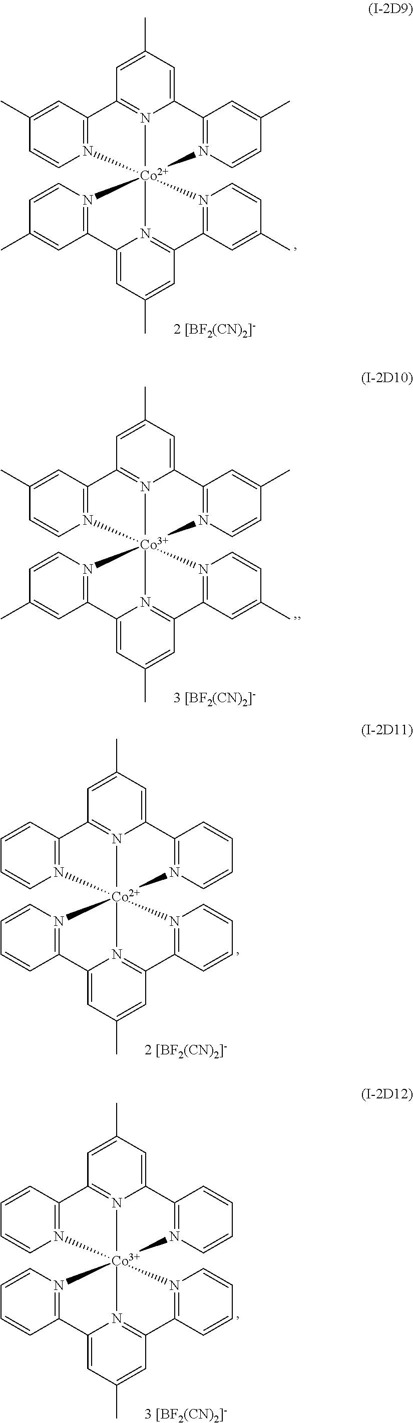

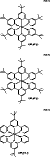

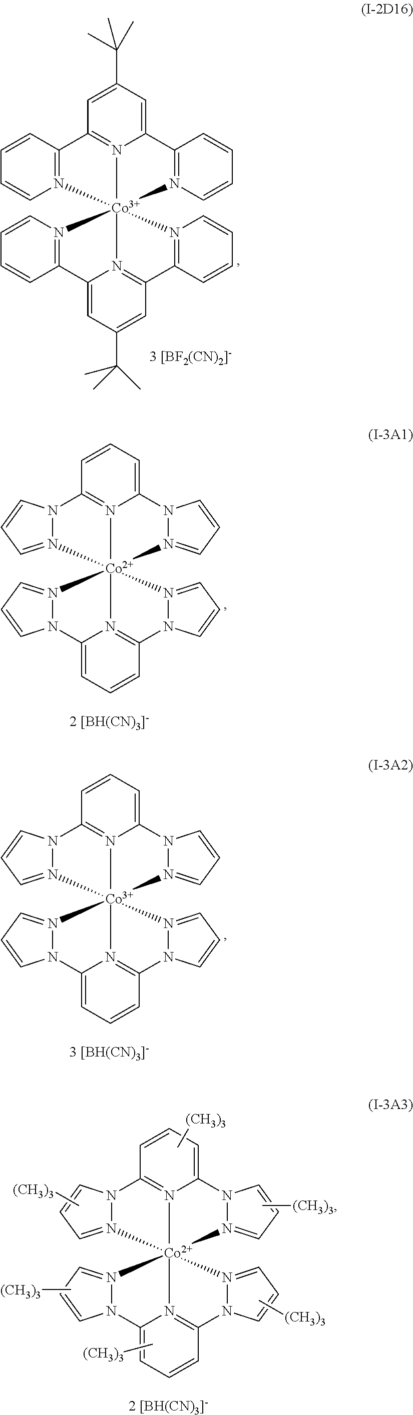

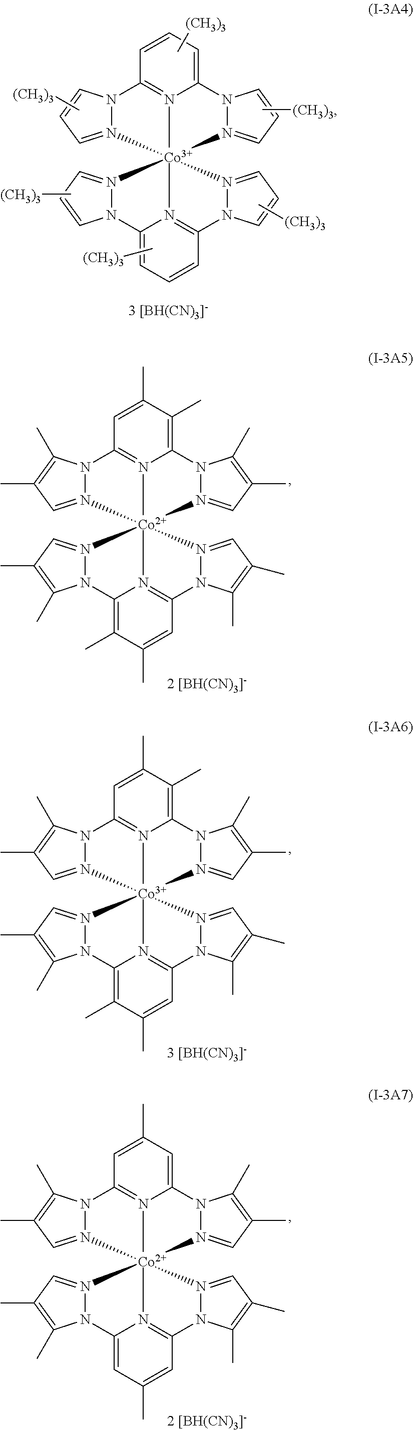

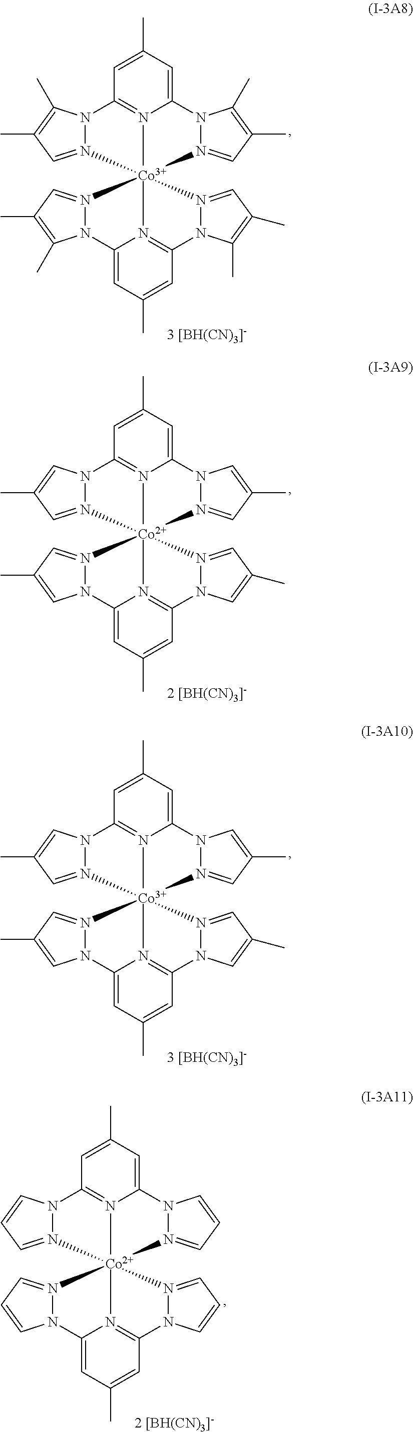

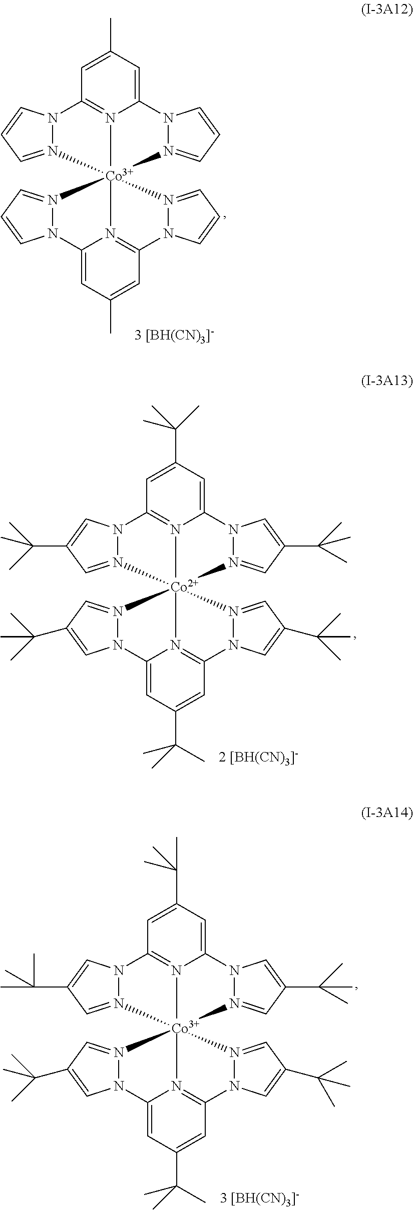

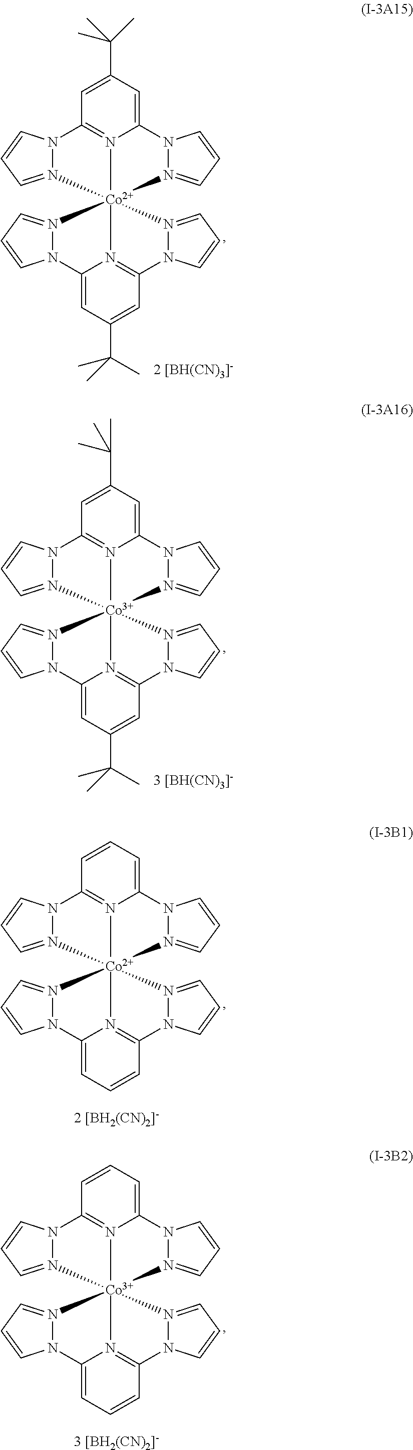

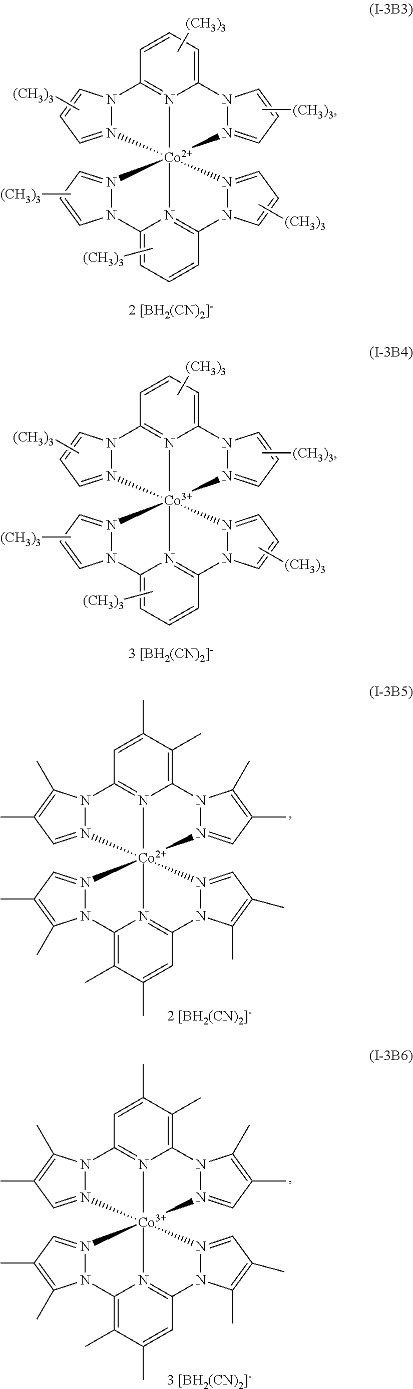

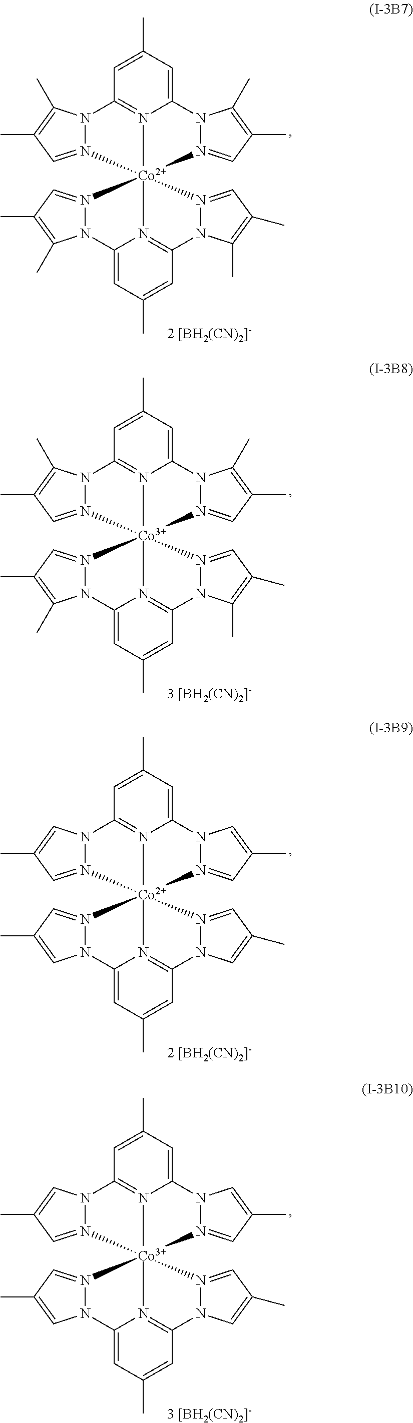

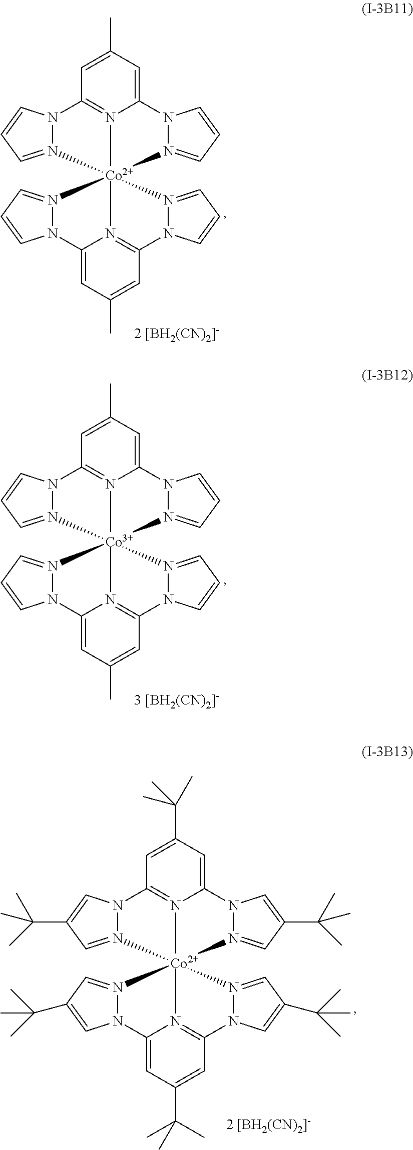

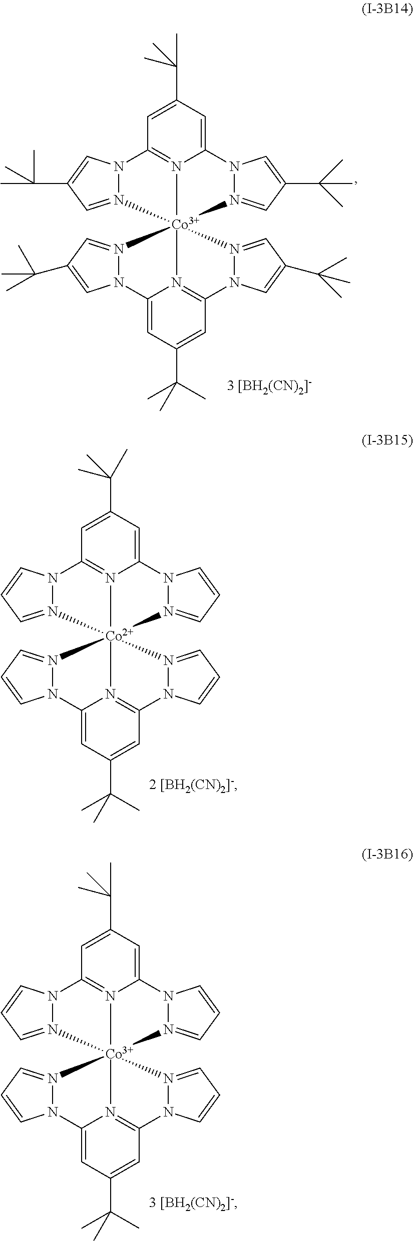

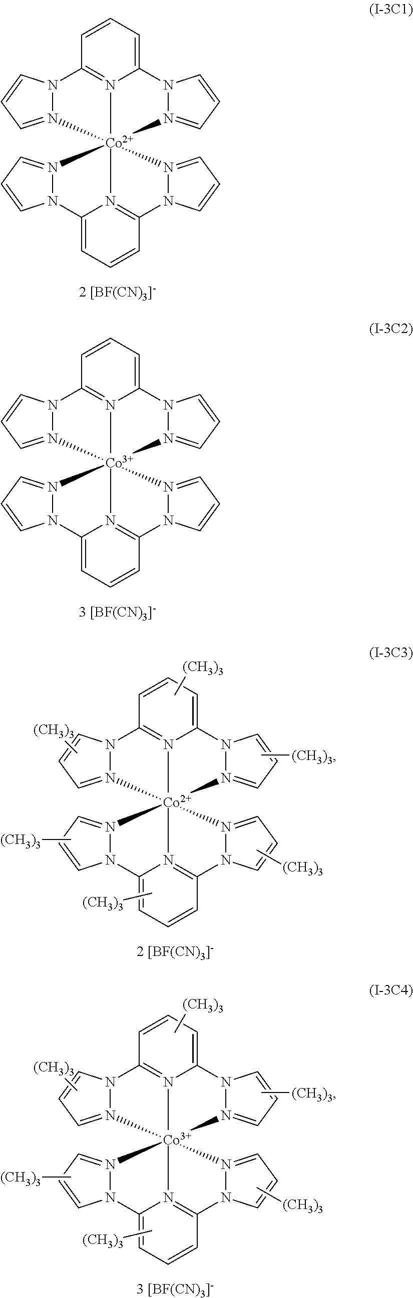

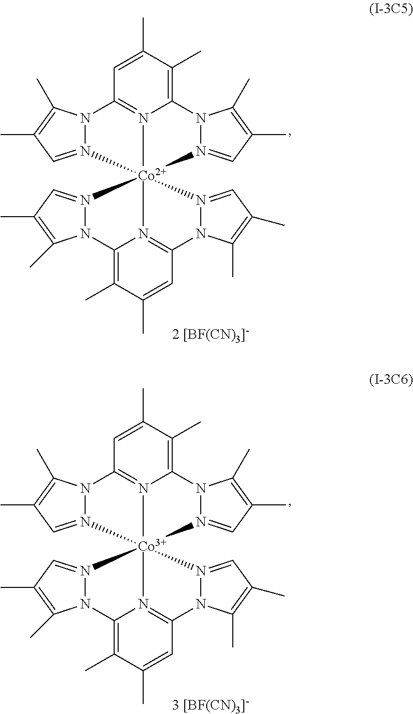

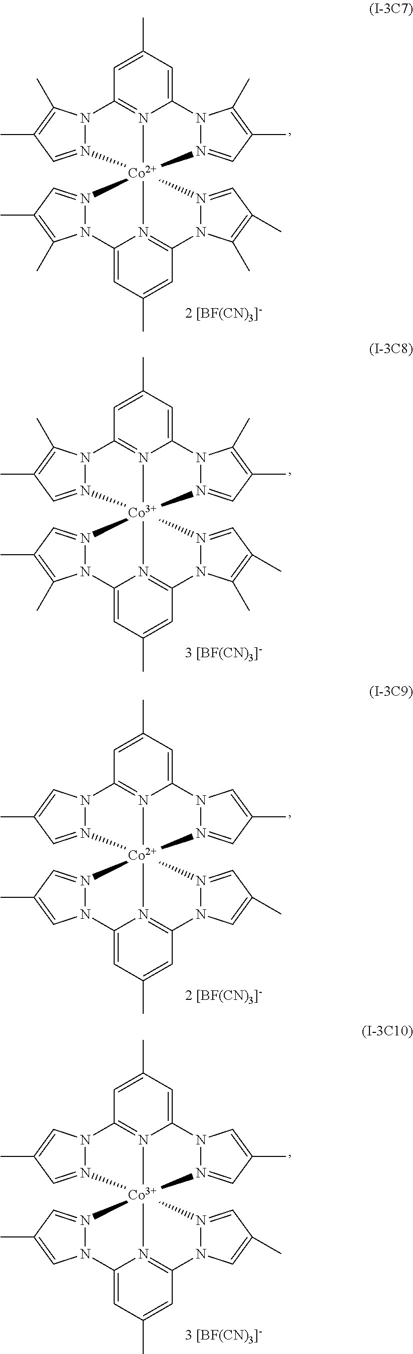

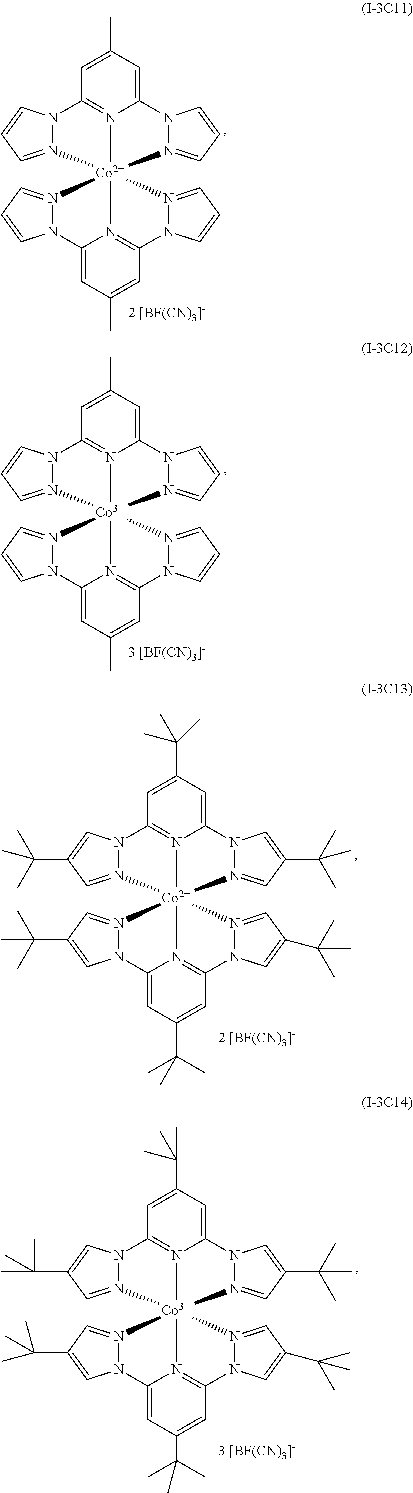

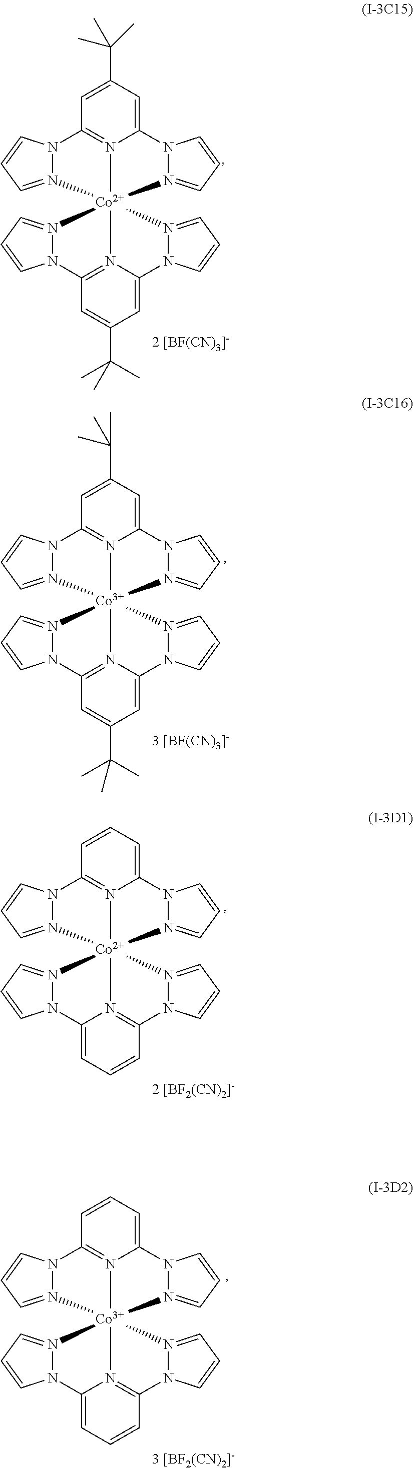

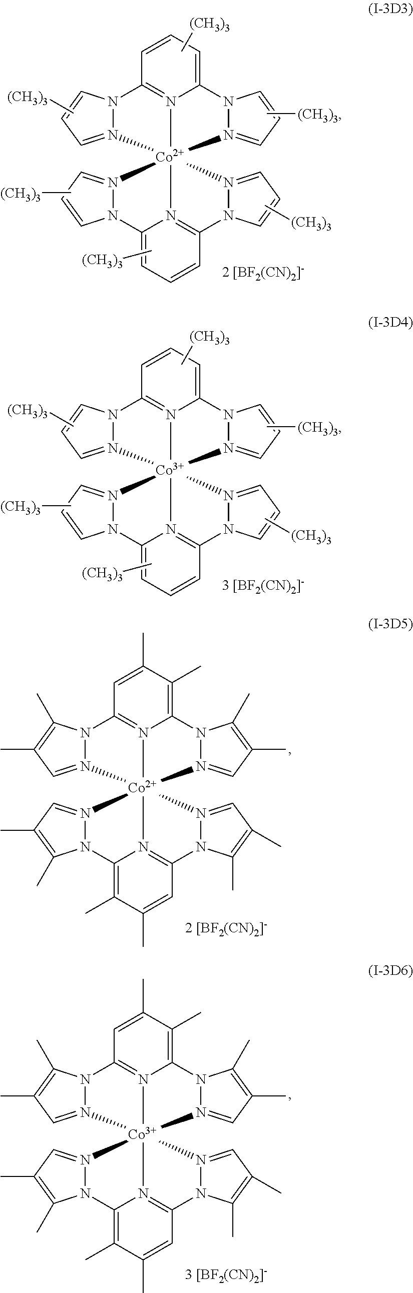

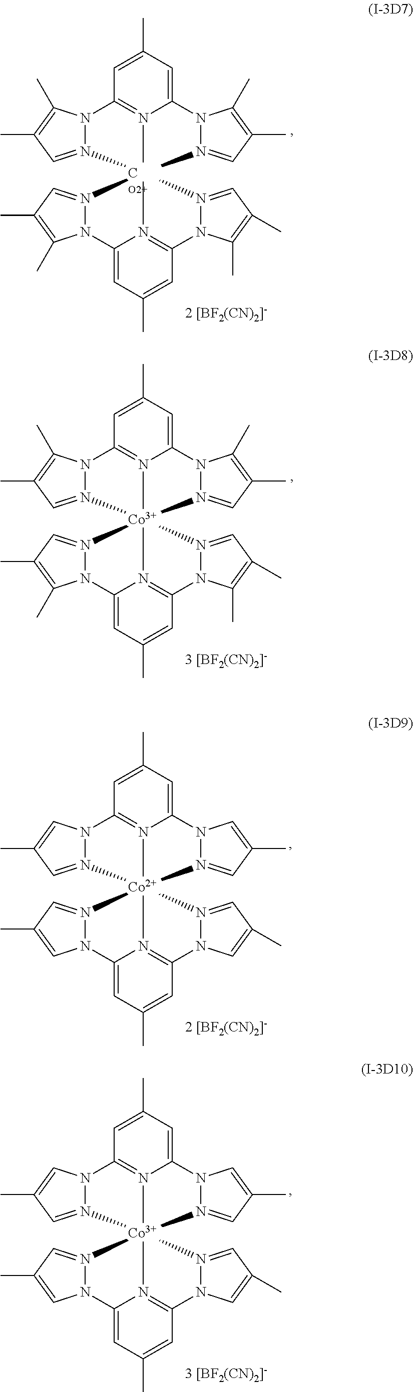

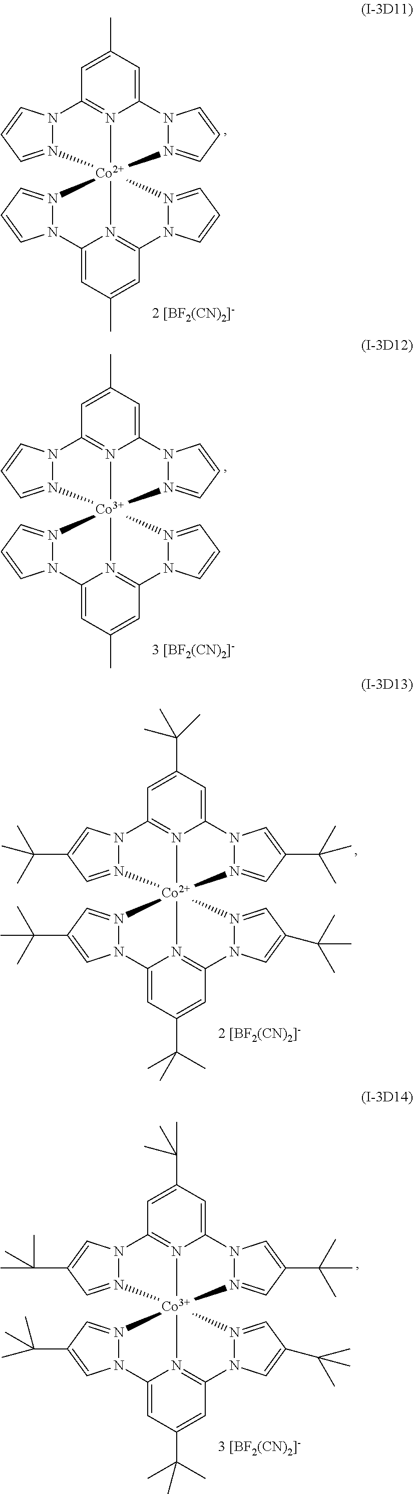

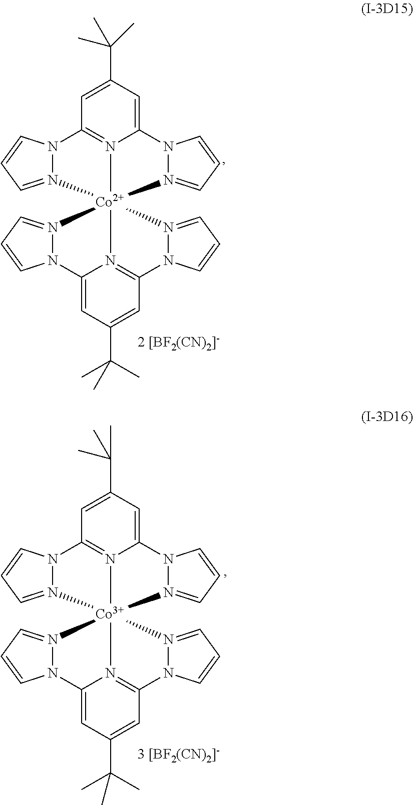

Examples of Co^{II}/Co^{III}-redox couples of formula (I) are the following mixtures:

I-1A1 and one compound selected from I-1A2, I-1A4, I-1A6, I-1A8, I-1A10, I-1A12, I-1A14, I-1A16, I-1A18, I-1A20; I-1A1 is preferably combined with I-1A2.

I-1A3 and one compound selected from I-1A2, I-1A4, I-1A6, I-1A8, I-1A10, I-1A12, I-1A14, I-1A16, I-1A18, I-1A20; I-1A3 is preferably combined with I-1A4.

I-1A5 and one compound selected from I-1A2, I-1A4, I-1A6, I-1A8, I-1A10, I-1A12, I-1A14, I-1A16, I-1A18, I-1A20; I-1A5 is preferably combined with I-1A6,

I-1A7 and one compound selected from I-1A2, I-1A4, I-1A6, I-1A8, I-1A10, I-1A12, I-1A14, I-1A16, I-1A18, I-1A20; I-1A7 is preferably combined with I-1A8,

I-1A9 and one compound selected from I-1A2, I-1A4, I-1A6, I-1A8, I-1A10, I-1A12, I-1A14, I-1A16, I-1A18, I-1A20; I-1A9 is preferably combined with I-1A10,

I-1A11 and one compound selected from I-1A2, I-1A4, I-1A6, I-1A8, I-1A10, I-1A12, I-1A14, I-1A16, I-1A18, I-1A20; I-1A11 is preferably combined with I-1A12,

I-1A13 and one compound selected from I-1A2, I-1A4, I-1A6, I-1A8, I-1A10, I-1A12, I-1A14, I-1A16, I-1A18, I-1A20; I-1A13 is preferably combined with I-1A14,

I-1A15 and one compound selected from I-1A2, I-1A4, I-1A6, I-1A8, I-1A10, I-1A12, I-1A14, I-1A16, I-1A18, I-1A20; I-1A15 is preferably combined with I-1A16,

I-1A17 and one compound selected from I-1A2, I-1A4, I-1A6, I-1A8, I-1A10, I-1A12, I-1A14, I-1A16, I-1A18, I-1A20; I-1A17 is preferably combined with I-1A18,

I-1A19 and one compound selected from I-1A2, I-1A4, I-1A6, I-1A8, I-1A10, I-1A12, I-1A14, I-1A16, I-1A18, I-1A20; I-1A19 is preferably combined with I-1A20,

I-1B1 and one compound selected from I-1B2, I-1B4, I-1B6, I-1B8, I-1B10, I-1B12, I-1B14, I-1B16, I-1B18, I-1B20; I-1B1 is preferably combined with I-1B2,

I-1B3 and one compound selected from I-1B2, I-1B4, I-1B6, I-1B8, I-1B10, I-1B12, I-1B14, I-1B16, I-1B18, I-1B20; I-1B3 is preferably combined with I-1B4,

I-1B5 and one compound selected from I-1B2, I-1B4, I-1B6, I-1B8, I-1B10, I-1B12, I-1B14, I-1B16, I-1B18, I-1B20; I-1B5 is preferably combined with I-1B6,

I-1B7 and one compound selected from I-1B2, I-1B4, I-1B6, I-1B8, I-1B10, I-1B12, I-1B14, I-1B16, I-1B18, I-1B20; I-1B7 is preferably combined with I-1B8,

I-1B9 and one compound selected from I-1B2, I-1B4, I-1B6, I-1B8, I-1B10, I-1B12, I-1B14, I-1B16, I-1B18, I-1B20; I-1B9 is preferably combined with I-1B10,

I-1B11 and one compound selected from I-1B2, I-1B4, I-1B6, I-1B8, I-1B10, I-1B12, I-1B14, I-1B16, I-1B18, I-1B20; I-1B11 is preferably combined with I-1B12,

I-1B13 and one compound selected from I-1B2, I-1B4, I-1B6, I-1B8, I-1B10, I-1B12, I-1B14, I-1B16, I-1B18, I-1B20; I-1B13 is preferably combined with I-1B14,

I-1B15 and one compound selected from I-1B2, I-1B4, I-1B6, I-1B8, I-1B10, I-1B12, I-1B14, I-1B16, I-1B18, I-1B20; I-1B15 is preferably combined with I-1B16,

I-1B17 and one compound selected from I-1B2, I-1B4, I-1B6, I-1B8, I-1B10, I-1B12, I-1B14, I-1B16, I-1B18, I-1B20; I-1B17 is preferably combined with I-1B18,

I-1B19 and one compound selected from I-1B2, I-1B4, I-1B6, I-1B8, I-1B10, I-1B12, I-1B14, I-1B16, I-1B18, I-1B20; I-1B19 is preferably combined with I-1B20,

I-1C1 and one compound selected from I-1C2, I-1C4, I-1C6, I-1C8, I-1C10, I-1C12, I-1C14, I-1C16, I-1C18, I-1C20; I-1C1 is preferably combined with I-C2,

I-1C3 and one compound selected I-1C2, I-1C4, I-1C6, I-1C8, I-1C10, I-1C12, I-1C14, I-1C16, I-1C18, I-1C20; I-1C3 is preferably combined with I-1C4,

I-1C5 and one compound selected from I-1C2, I-1C4, I-1C6, I-1C8, I-1C10, I-1C12, I-1C14, I-1C16, I-1C18, I-1C20; I-1C5 is preferably combined with I-1C6,

I-1C7 and one compound selected from I-1C2, I-1C4, I-1C6, I-1C8, I-1C10, I-1C12, I-1C14, I-1C16, I-1C18, I-1C20; I-1C7 is preferably combined with I-1C8,

I-1C9 and one compound selected from I-1C2, I-1C4, I-1C6, I-1C8, I-1C10, I-1C12, I-1C14, I-1C16, I-1C18, I-1C20; I-1C9 is preferably combined with I-1C10,

I-1C11 and one compound selected from I-1C2, I-1C4, I-1C6, I-1C8, I-1C10, I-1C12, I-1C14, I-1C16, I-1C18, I-1C20; I-1C11 is preferably combined with I-1C12,

I-1C13 and one compound selected from I-1C2, I-1C4, I-1C6, I-1C8, I-1C10, I-1C12, I-1C14, I-1C16, I-1C18, I-1C20; I-1C13 is preferably combined with I-1C14,

I-1C15 and one compound selected from I-1C2, I-1C4, I-1C6, I-1C8, I-1C10, I-1C12, I-1C14, I-1C16, I-1C18, I-1C20; I-1C15 is preferably combined with I-1C16,

I-1C17 and one compound selected from I-1C2, I-1C4, I-1C6, I-1C8, I-1C10, I-1C12, I-1C14, I-1C16, I-1C18, I-1C20; I-1C17 is preferably combined with I-1C18,

I-1C19 and one compound selected from I-1C2, I-1C4, I-1C6, I-1C8, I-1C10, I-1C12, I-1C14, I-1C16, I-1C18, I-1C20; I-1C19 is preferably combined with I-1C20,

I-1D1 and one compound selected from I-1D2, I-1D4, I-1D6, I-1D8, I-1D10, I-1D12, I-1D14, I-1D16, I-1D18, I-1D20; I-1D1 is preferably combined with I-1D2,

I-1D3 and one compound selected from I-1D2, I-1D4, I-1D6, I-1D8, I-1D10, I-1D12, I-1D14, I-1D16, I-1D18, I-1D20; I-1D3 is preferably combined with I-1D4,

I-1D5 and one compound selected from I-1D2, I-1D4, I-1D6, I-1D8, I-1D10, I-1D12, I-1D14, I-1D16, I-1D18, I-1D20; I-1D5 is preferably combined with I-1D6,

I-1D7 and one compound selected from I-1D2, I-1D4, I-1D6, I-1D8, I-1D10, I-1D12, I-1D14, I-1D16, I-1D18, I-1D20; I-1D7 is preferably combined with I-1D8,

I-1D9 and one compound selected from I-1D2, I-1D4, I-1D6, I-1D8, I-1D10, I-1D12, I-1D14, I-1D16, I-1D18, I-1D20; I-1D9 is preferably combined with I-1D10,

I-1D11 and one compound selected from I-1D2, I-1D4, I-1D6, I-1D8, I-1 D10, I-1D12, I-1D14, I-1D16, I-1D18, I-1D20; I-1D11 is preferably combined and I-1D12,

I-1D13 and one compound selected from I-1D2, I-1D4, I-1D6, I-1D8, I-1 D10, I-1D12, I-1D14, I-1D16, I-1D18, I-1D20; I-1D13 is preferably combined with I-1D14,

I-1D15 and one compound selected I-1D2, I-1D4, I-1D6, I-1D8, I-1D10, I-1D12, I-1D14, I-1D16, I-1D18, I-1D20; I-1D15 is preferably combined with I-1D16,

I-1D17 and one compound selected from I-1D2, I-1D4, I-1D6, I-1D8, I-1 D10, I-1D12, I-1D14, I-1D16, I-1D18, I-1D20; I-1D17 is preferably combined with I-1D18,

I-1D19 and one compound selected from I-1D2, I-1D4, I-1D6, I-1D8, I-1 D10, I-1D12, I-1D14, I-1D16, I-1D18, I-1D20; I-1D19 is preferably combined with I-1D20,

I-2A1 and one compound selected from I-2A2, I-2A4, I-2A6, I-2A8, I-2A10, I-2A12, I-2A14, I-2A16; I-2A1 is preferably combined with I-2A2.

I-2A3 and one compound selected from I-2A2, I-2A4, I-2A6, I-2A8, I-2A10, I-2A12, I-2A14, I-2A16; I-2A3 is preferably combined with I-2A4.

I-2A5 and one compound selected from I-2A2, I-2A4, I-2A6, I-2A8, I-2A10, I-2A12, I-2A14, I-2A16; I-2A5 is preferably combined with I-2A6,

I-2A7 and one compound selected from I-2A2, I-2A4, I-2A6, I-2A8, I-2A10, I-2A12, I-2A14, I-2A16; I-2A7 is preferably combined with I-2A8,

I-2A9 and one compound selected from I-2A2, I-2A4, I-2A6, I-2A8, I-2A10, I-2A12, I-2A14, I-2A16; I-2A9 is preferably combined with I-2A10,

I-2A11 and one compound selected from I-2A2, I-2A4, I-2A6, I-2A8, I-2A10, I-2A12, I-2A14, I-2A16; I-2A11 is preferably combined with I-2A12,

I-2A13 and one compound selected from I-2A2, I-2A4, I-2A6, I-2A8, I-2A10, I-2A12, I-2A14, I-2A16; I-2A13 is preferably combined with I-2A14,

I-2A15 and one compound selected from I-2A2, I-2A4, I-2A6, I-2A8, I-2A10, I-2A12, I-2A14, I-2A16; I-2A15 is preferably combined with I-2A16,

I-2B1 and one compound selected from I-2B2, I-2B4, I-2B6, I-2B8, I-2B10, I-2B12, I-2B14, I-2B16; I-2B1 is preferably combined with I-2B2,

I-2B3 and one compound selected from I-2B2, I-2B4, I-2B6, I-2B8, I-2B10, I-2B12, I-2B14, I-2B16; I-2B3 is preferably combined with I-2B4,

I-2B5 and one compound selected from I-2B2, I-2B4, I-2B6, I-2B8, I-2B10, I-2B12, I-2B14, I-2B16; I-2B5 is preferably combined with I-2B6,

I-2B7 and one compound selected from I-2B2, I-2B4, I-2B6, I-2B8, I-2B10, I-2B12, I-2B14, I-2B16; I-2B7 is preferably combined with I-2B8,

I-2B9 and one compound selected from I-2B2, I-2B4, I-2B6, I-2B8, I-2B10, I-2B12, I-2B14, I-2B16; I-2B9 is preferably combined with I-2B10,

I-2B11 and one compound selected from I-2B2, I-2B4, I-2B6, I-2B8, I-2B10, I-2B12, I-2B14, I-2B16; I-2B11 is preferably combined with I-2B12,

I-2B13 and one compound selected from I-2B2, I-2B4, I-2B6, I-2B8, I-2B10, I-2B12, I-2B14, I-2B16; I-2B13 is preferably combined with I-2B14,

I-2B15 and one compound selected from I-2B2, I-2B4, I-2B6, I-2B8, I-2B10, I-2B12, I-2B14, I-2B16; I-2B15 is preferably combined with I-2B16,

I-2C1 and one compound selected from I-2C2, I-2C4, I-2C6, I-2C8, I-2C10, I-2C12, I-2C14, I-2C16; I-2C1 is preferably combined with I-2C2,

I-2C3 and one compound selected I-2C2, I-2C4, I-2C6, I-2C8, I-2C10, I-2C12, I-2C14, I-2C16; I-2C3 is preferably combined with I-2C4,

I-2C5 and one compound selected from I-2C2, I-2C4, I-2C6, I-2C8, I-2C10, I-2C12, I-2C14, I-2C16; I-2C5 is preferably combined with I-2C6,

I-2C7 and one compound selected from I-2C2, I-2C4, I-2C6, I-2C8, I-2C10, I-2C12, I-2C14, I-2C16; I-2C7 is preferably combined with I-2C8,

I-2C9 and one compound selected from I-2C2, I-2C4, I-2C6, I-2C8, I-2C10, I-2C12, I-2C14, I-2C16; I-2C9 is preferably combined with I-2C10,

I-2C11 and one compound selected from I-2C2, I-2C4, I-2C6, I-2C8, I-2C10, I-2C12, I-2C14, I-2C16; I-2C11 is preferably combined with I-2C12,

I-2C13 and one compound selected from I-2C2, I-2C4, I-2C6, I-2C8, I-2C10, I-2C12, I-2C14, I-2C16; I-2C13 is preferably combined with I-2C14,

I-2C15 and one compound selected from I-2C2, I-2C4, I-2C6, I-2C8, I-2C10, I-2C12, I-2C14, I-2C16; I-2C15 is preferably combined with I-2C16,

I-2D1 and one compound selected from I-2D2, I-2D4, I-2D6, I-2D8, I-2D10, I-2D12, I-2D14, I-2D16; I-2D1 is preferably combined with I-2D2,

I-2D3 and one compound selected from I-2D2, I-2D4, I-2D6, I-2D8, I-2D10, I-2D12, I-2D14, I-2D16; I-2D3 is preferably combined with I-2D4,

I-2D5 and one compound selected from I-2D2, I-2D4, I-2D6, I-2D8, I-2D10, I-2D12, I-2D14, I-2D16; I-2D5 is preferably combined with I-2D6,

I-2D7 and one compound selected from I-2D2, I-2D4, I-2D6, I-2D8, I-2D10, I-2D12, I-2D14, I-2D16; I-2D7 is preferably combined with I-2D8,

I-2D9 and one compound selected from I-2D2, I-2D4, I-2D6, I-2D8, I-2D10, I-2D12, I-2D14, I-2D16; I-2D9 is preferably combined with I-2D10,

I-2D11 and one compound selected from I-2D2, I-2D4, I-2D6, I-2D8, I-2D10, I-2D12, I-2D14, I-2D16; I-2D11 is preferably combined and I-2D12,

I-2D13 and one compound selected from I-2D2, I-2D4, I-2D6, I-2D8, I-2D10, I-2D12, I-2D14, I-2D16; I-2D13 is preferably combined with I-2D14,

I-2D15 and one compound selected I-2D2, I-2D4, I-2D6, I-2D8, I-2D10, I-2D12, I-2D14, I-2D16; I-2D15 is preferably combined with I-2D16,

I-3A1 and one compound selected from I-3A2, I-3A4, I-3A6, I-3A8, I-3A10, I-3A12, I-3A14, I-3A16; I-3A1 is preferably combined with I-3A2.

I-3A3 and one compound selected from I-3A2, I-3A4, I-3A6, I-3A8, I-3A10, I-3A12, I-3A14, I-3A16; I-3A3 is preferably combined with I-3A4.

I-3A5 and one compound selected from I-3A2, I-3A4, I-3A6, I-3A8, I-3A10, I-3A12, I-3A14, I-3A16; I-3A5 is preferably combined with I-3A6,

I-3A7 and one compound selected from I-3A2, I-3A4, I-3A6, I-3A8, I-3A10, I-3A12, I-3A14, I-3A16; I-3A7 is preferably combined with I-3A8,

I-3A9 and one compound selected from I-3A2, I-3A4, I-3A6, I-3A8, I-3A10, I-3A12, I-3A14, I-3A16; I-3A9 is preferably combined with I-3A10,

I-3A11 and one compound selected from I-3A2, I-3A4, I-3A6, I-3A8, I-3A10, I-3A12, I-3A14, I-3A16; I-3A11 is preferably combined with I-3A12,

I-3A13 and one compound selected from I-3A2, I-3A4, I-3A6, I-3A8, I-3A10, I-3A12, I-3A14, I-3A16; I-3A13 is preferably combined with I-3A14,

I-3A15 and one compound selected from I-3A2, I-3A4, I-3A6, I-3A8, I-3A10, I-3A12, I-3A14, I-3A16; I-3A15 is preferably combined with I-3A16,

I-3B1 and one compound selected from I-3B2, I-3B4, I-3B6, I-3B8, I-3B10, I-3B12, I-3B14, I-3B16; I-3B1 is preferably combined with I-3B2,

I-3B3 and one compound selected from I-3B2, I-3B4, I-3B6, I-3B8, I-3B10, I-3B12, I-3B14, I-3B16; I-3B3 is preferably combined with I-3B4,

I-3B5 and one compound selected from I-3B2, I-3B4, I-3B6, I-3B8, I-3B10, I-3B12, I-3B14, I-3B16; I-3B5 is preferably combined with I-3B6,

I-3B7 and one compound selected from I-3B2, I-3B4, I-3B6, I-3B8, I-3B10, I-3B12, I-3B14, I-3B16; I-3B7 is preferably combined with I-3B8,

I-3B9 and one compound selected from I-3B2, I-3B4, I-3B6, I-3B8, I-3B10, I-3B12, I-3B14, I-3B16; I-3B9 is preferably combined with I-3B10,

I-3B11 and one compound selected from I-3B2, I-3B4, I-3B6, I-3B8, I-3B10, I-3B12, I-3B14, I-3B16; I-3B11 is preferably combined with I-3B12,

I-3B13 and one compound selected from I-3B2, I-3B4, I-3B6, I-3B8, I-3B10, I-3B12, I-3B14, I-3B16; I-3B13 is preferably combined with I-3B14,

I-3B15 and one compound selected from I-3B2, I-3B4, I-3B6, I-3B8, I-3B10, I-3B12, I-3B14, I-3B16; I-3B15 is preferably combined with I-3B16,

I-3C1 and one compound selected from I-3C2, I-3C4, I-3C6, I-3C8, I-3C10, I-3C12, I-3C14, I-3C16; I-3C1 is preferably combined with I-3C2,

I-3C3 and one compound selected I-3C2, I-3C4, I-3C6, I-3C8, I-3C10, I-3C12, I-3C14, I-3C16; I-3C3 is preferably combined with I-3C4,

I-3C5 and one compound selected from I-3C2, I-3C4, I-3C6, I-3C8, I-3C10, I-3C12, I-3C14, I-3C16; I-3C5 is preferably combined with I-3C6,

I-3C7 and one compound selected from I-3C2, I-3C4, I-3C6, I-3C8, I-3C10, I-3C12, I-3C14, I-3C16; I-3C7 is preferably combined with I-3C8,

I-3C9 and one compound selected from I-3C2, I-3C4, I-3C6, I-3C8, I-3C10, I-3C12, I-3C14, I-3C16; I-3C9 is preferably combined with I-3C10,

I-3C11 and one compound selected from I-3C2, I-3C4, I-3C6, I-3C8, I-3C10, I-3C12, I-3C14, I-3C16; I-3C11 is preferably combined with I-3C12,

I-3C13 and one compound selected from I-3C2, I-3C4, I-3C6, I-3C8, I-3C10, I-3C12, I-3C14, I-3C16; I-3C13 is preferably combined with I-3C14,

I-3C15 and one compound selected from I-3C2, I-3C4, I-3C6, I-3C8, I-3C10, I-3C12, I-3C14, I-3C16; I-3C15 is preferably combined with I-3C16,

I-3D1 and one compound selected from I-3D2, I-3D4, I-3D6, I-3D8, I-3D10, I-3D12, I-3D14, I-3D16; I-3D1 is preferably combined with I-3D2,

I-3D3 and one compound selected from I-3D2, I-3D4, I-3D6, I-3D8, I-3D10, I-3D12, I-3D14, I-3D16; I-3D3 is preferably combined with I-3D4,

I-3D5 and one compound selected from I-3D2, I-3D4, I-3D6, I-3D8, I-3D10, I-3D12, I-3D14, I-3D16; I-3D5 is preferably combined with I-3D6,

I-3D7 and one compound selected from I-3D2, I-3D4, I-3D6, I-3D8, I-3D10, I-3D12, I-3D14, I-3D16; I-3D7 is preferably combined with I-3D8,

I-3D9 and one compound selected from I-3D2, I-3D4, I-3D6, I-3D8, I-3D10, I-3D12, I-3D14, I-3D16; I-3D9 is preferably combined with I-3D10,

I-3D11 and one compound selected from I-3D2, I-3D4, I-3D6, I-3D8, I-3D10, I-3D12, I-3D14, I-3D16; I-3D11 is preferably combined and I-3D12,

I-3D13 and one compound selected from I-3D2, I-3D4, I-3D6, I-3D8, I-3D10, I-3D12, I-3D14, I-3D16; I-3D13 is preferably combined with I-3D14,

I-3D15 and one compound selected I-3D2, I-3D4, I-3D6, I-3D8, I-3D10, I-3D12, I-3D14, I-3D16; I-3D15 is preferably combined with I-3D16.

Compounds of formula (I) in which n is 2 can be synthesized through reaction of a compound of formula (II)

Kt[BX_{z}(CN)_{4-z}] (II),

in which

X is H or F,

z is 1 or 2 and

Kt is an alkali metal cation

with Cobalt dichloride or a hydrate thereof and with at least two equivalents of a compound of formula (III)

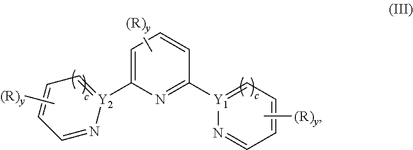

in which

Y₁ and Y₂ are each independently C or N,

c is 0 in the case Y₁ and/or Y₂ are N,

c is 1 in the case Y₁ and/or Y₂ are C,

y is each independently 0, 1, 2, 3 or 4,

R is each independently a straight-chain or branched alkyl group with 1 to 20 C atoms.

Compounds of formula (I) in which n is 3 can be synthesized through reaction of a compound of formula (II)

Kt[BX_{z}(CN)_{4-z}] (II),

in which

X is H or F,

z is 1 or 2 and

Kt is an alkali metal cation

with Cobalt dichloride or a hydrate thereof and with at least two equivalents of a compound of formula (III)

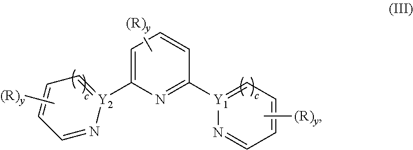

in which

Y₁ and Y₂ are each independently C or N,

c is 0 in the case Y₁ and/or Y₂ are N,

c is 1 in the case Y₁ and/or Y₂ are C,

y is each independently 0, 1, 2, 3 or 4,

R is each independently a straight-chain or branched alkyl group with 1 to 20 C atoms,

in the presence of an oxidant.

The oxidant or oxidizer may be selected from chlorine gas, bromine, aqueous NaOCl or H₂O₂. It is preferred to use chlorine gas.

Compounds of formula (II) are preferably potassium or sodium salts, particularly preferred potassium salts. In case X is F, the alkali metal salts are commercially available or may be synthesized according to WO 2004/072089, especially as disclosed in examples 11 and 12.

Alkali metal salts of formula (II) in which X is H and z is 1 (formula II-A)

[Kt][BH(CN)₃] (II-A)

can be synthesized through reaction of an alkali metal tetracyanoborate [Me¹][B(CN)₄] with an alkali metal [Me],

where [Me¹] denotes an alkali metal cation which is different or equal to the alkali metal [Me] resulting in the formation of a compound of formula (IV)

{[Me]⁺}₂[B(CN)₃]²⁻ (IV)

in which [Me]⁺ denotes the alkali metal cation of the alkali metal followed by the protonation of the compound of formula (IV) resulted from the previous reaction.

Alkali metal tetracyanoborates can be synthesized according to WO 2004/072089, especially as disclosed in examples 1 to 3.

Alkali metals are commercially available materials.

[Me¹]⁺ is preferably K⁺ or Na⁺, especially preferably K⁺. [Me] is preferably lithium, sodium, potassium or their mixtures, especially preferably sodium.

The process for the preparation of compounds of the formula (II-A) in which [Kt] is an alkali metal cation as described above is carried out in liquid ammonia or in organic solvents which are inert to alkali metals, for example tetrahydrofuran, dialkyl ethers or amide-based solvents. If reaction proceeds in organic solvent the application of some catalysts, for example benzophenone, can accelerate the process and improve the yield of compounds of formula (IV).

Useful amide solvents are N,N-dimethylformamide, N,N-dimethylacetamide, N-methylpyrrolidone or HMPT (hexamethylphosphortriamide).

Liquid ammonia is condensed at temperatures around −78° C. and the reaction mixture is warmed up to a temperature between −50° C. to −30° C. in the presence of an inert atmosphere, like nitrogen or argon followed by warming up to 10° C. to 30° C. and evaporation of ammonia.

The protonation in step 2 is preferably carried out in water at temperatures between 15° C. and 30° C., preferably at room temperature, in the absence or in the presence of an inorganic base such as alkali metal carbonates or acetates, or organic bases, preferably trialkylamines. For the protonation in step 2, any source of proton can be used beside water, for example alcohols, carboxylic acids, mineral acids, tertiary ammonium salts such as [R₃NH⁺Cl⁻] in which R is each independently a straight-chain or branched alkyl group with 1 to 4 C atoms or [NH₄Cl].

It is preferable to purify the compounds of formula (II-A) by extraction with an organic solvent.

Useful organic solvents are for example, acetonitrile, dimethoxyethane, diglyme, tetrahydrofurane, or methyl-tert-butyl ether.

Alkali metal salts of formula II in which X is H and z is 2 (formula (II-B))

[Kt][BH₂(CN)₂] (II-B)

may be synthesized according to or based on already known methods as described in Zhang Y. and Shreeve J. M. Angew. Chem. 2011, 123, 965-967; Spielvogel B. F. et al, Inorg. Chem. 1984, 23, 3262-3265; Das M. K. et al, Bull. Chem. Soc. Jpn., 63, 1281-1283, 1990 and B. Györi et al, Journal of Organometallic Chemistry, 255, 1983, 17-28.

Compounds of formula (II-B) in which [Kt] is Na⁺ can be prepared additionally in a very simple way through reaction of sodium tetrahydrido-borate with trialkylsilylcyanide in which the alkyl groups independently denotes straight-chain or branched alkyl groups having 1 to 4 C atoms.

This process can be carried out in air, preferably in a dry atmosphere, for example under dry air, nitrogen or argon and may be carried out in an organic solvent or in the absence of an organic solvent if one starting material is liquid at the reaction temperature, at a temperature between 10° C. and 200° C.

Useful organic solvents are for example, acetonitrile, dimethoxyethane, diglyme, tetrahydrofurane, or methyl-tert-butyl ether.

Sodium tetrahydrido-borate and trimethylsilylcyanide are commercially available.

Cobalt dichloride or hydrates thereof and compounds of formula (III-1) and (III-2)

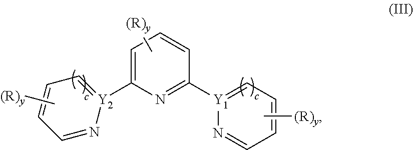

in which

Y₁ and Y₂ are each independently C or N,

c is 0 in the case Y₁ and/or Y₂ are N,

c is 1 in the case Y₁ and/or Y₂ are C,

y is each independently 0, 1, 2, 3 or 4,

R is each independently a straight-chain or branched alkyl group with 1 to 20 C atoms,

are commercially available or can be synthesized according to already known methods in the art as described in “Organikum”, 2001, WILEY-VCH, Weinheim; R. C. Larock, “Comprehensive Organic Transformations, A Guide to Functional Group Preparations”, Second Edition, 1999, WILEY-VCH, N. Y. Chichester, Weinheim.

For example, 6-(N-pyrazolyl)2,2′-bipyridine can be synthesized based on Alison J. Downard et al, Inorg. Chem., 1991, 30, 3733 or WO 2012/114315. For example, 2,6-bis(N-pyrazolyl)pyridines can be synthesized e.g. as described in Malcolm A. Halcrow, Coord. Chem. Rev. 2005, 249, 2880-2908.

For example, 2,2′:6′,2″-terpyridine is commercially available from Sigma Aldrich, article no. 234672.

The synthesis of compounds of formula (I) in which n is 2 or 3 is carried out in water or a mixture of water and an organic solvent, preferably water and methanol, and the preferred reaction temperature is room temperature.

Therefore, the invention also relates to a process for the preparation of compounds of formula (I) in which n is 2 comprising the reaction of a compound of formula (II)

Kt[BX_{z}(CN)_{4-z}] (II),

in which

X is H or F,

z is 1 or 2 and

Kt is an alkali metal cation

with Cobalt dichloride or a hydrate thereof and with at least two equivalents of a compound of formula (III)

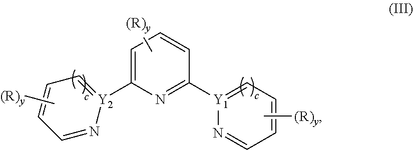

in which

Y₁ and Y₂ are each independently C or N,

c is 0 in the case Y₁ and/or Y₂ are N,

c is 1 in the case Y₁ and/or Y₂ are C,

y is each independently 0, 1, 2, 3 or 4,

R is each independently a straight-chain or branched alkyl group with 1 to 20 C atoms.

In addition, the invention also relates to a process for the preparation of compounds of formula (I) in which n is 3 comprising the reaction of a compound of formula (II)

Kt[BX_{z}(CN)_{4-z}] (II),

in which

X is H or F,

z is 1 or 2 and

Kt is an alkali metal cation

with Cobalt dichloride or a hydrate thereof and with at least two equivalents of a compound of formula (III)

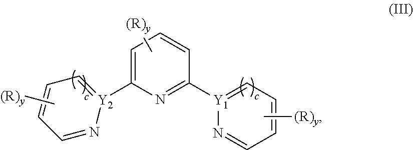

in which

Y₁ and Y₂ are each independently C or N,

c is 0 in the case Y₁ and/or Y₂ are N,

c is 1 in the case Y₁ and/or Y₂ are C,

y is each independently 0, 1, 2, 3 or 4,

R is each independently a straight-chain or branched alkyl group with 1 to 20 C atoms,

in the presence of an oxidant.

The compounds of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C), (I-3D), especially the Co^{II}/Co^{III}-redox couples of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C), (I-3D) as explained before according to this invention, are preferably used in electrochemical and/or optoelectronic devices, especially in electrolyte formulations.

The present invention therefore relates furthermore to an electrolyte formulation comprising at least one compound of formula (I) as described above or preferably described herein.

The present invention therefore relates furthermore to an electrolyte formulation comprising at least one compound of formula (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) described above or preferably described herein.

It is preferred that at least two compounds of formula (I) are comprised one compound corresponding to formula (Ia) and the other corresponding to formula (Ib) as described before and defined as Co^{II}/Co^{III}-redox couple of formula (I).

The present invention therefore relates furthermore to an electrolyte formulation comprising at least one Co^{II}/Co^{III}-redox couple of formula (I) as described above or preferably described herein.

The present invention therefore relates furthermore to an electrolyte formulation comprising at least one Co^{II}/Co^{III}-redox couple of formula (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) as described above or preferably described herein.

Electrolyte formulations comprising at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C), (I-3D) as described or preferably described before or comprising at least one Co^{II}/Co^{III}-redox couple of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C), (I-3D) as described above or preferably described before, can be preferably used in electrochemical and/or optoelectronic devices such as a photovoltaic cell, a light emitting device, an electrochromic or photo-electrochromic device, an electrochemical sensor and/or biosensor.

Electrolyte formulations according to the invention can be preferably used in photovoltaic cells, preferably in dye sensitized solar cells.

Such electrolyte formulations form a crucial part of the disclosed devices and the performance of the device largely depends on the physical and chemical properties of the various components of these electrolytes.

Electrolyte formulations according to the invention are alternatives to already known electrolyte formulations. They show in the field of electrolyte formulations of dye sensitized solar cells a better performance of DSSC in comparison to the already known Co^{II}/Co^{III}-redox couples with other anions. DSSC's according to the invention show a higher short-circuit current density (I_{sc}) and a better solar-to-electric power-conversion efficiency (PCE, η).

In chemistry, an electrolyte is any substance containing free ions that make the substance electrically conductive. The most typical electrolyte is an ionic solution, but molten electrolytes and solid electrolytes are also possible.

An electrolyte formulation according to the invention is therefore an electrically conductive medium, basically due to the presence of at least one substance that is present in a dissolved and or in molten state and undergo dissociation into ionic species, i.e. supporting an electric conductivity via motion of ionic species. However, the said electric conductivity may not be of the major relevance to the role of the electrolyte of a dye-sensitised solar cell. Therefore, the scope of this invention is not limited to highly conductive electrolyte media.

The term electrolyte may be used for the term electrolyte formulation as well comprising all ingredients as disclosed for the electrolyte formulation.

The electrolyte formulation may include or comprise, essentially consist of or consist of the said requisite or optional constituents. All compounds or components which can be used in the preparations are either known and commercially available or can be synthesised by known or already described processes.

Typical molar concentrations of at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) as described above in the electrolyte formulations range from 0.01 M to 0.5 M, preferably from 0.05 M to 0.3 M. This molar concentration in the electrolyte may be achieved with one or more compounds of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D).

In general, it is preferred that the molar concentration of the at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) in which n is 2 range from 0.1 to 0.3 M.

In general, it is preferred that the molar concentration of at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) in which n is 2 range from 0.1 to 0.3 M, preferably 0.2 to 0.25 M, and the molar concentration of at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) in which n is 3 building the at least one CoII/CoIII-redox couple of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) range from 0.01 to 0.1 M, preferably 0.04 to 0.05 M.

For the purpose of the present invention, the molar concentration refer to the concentration at 25° C.

The present electrolyte formulation may furthermore comprise a further redox active species such as iodide/tri-iodide, Ferrocene derivatives or Co(II)/Co(III) complex salts such as Co(II)/Co(III)(dbbip)₂ in which dbbip means 2,6-bis(1′-butylbenzimidazol-2′-yl)pyridine, the counter anion being either perchlorate, fluoroperfluoroalkylphosphate such as perfluoroethylpentafluorophosphate or tetracyanoborate.

Other components of the electrolyte formulation are one or several further salts, e.g. ionic liquids, solvents, and other additives, as indicated further below.

The electrolyte formulation of the present invention comprises an organic solvent and/or comprises one or more ionic liquids.

Organic solvents may be selected from those disclosed in the literature. Preferably, the solvent, if present, has a boiling point higher than 160 degrees centigrade, more preferably higher than 190 degrees such as propylene carbonate, ethylene carbonate, butylene carbonate, gamma-butyrolactone, gamma-valerolactone, glutaronitrile, adiponitrile, N-methyloxazolidinone, N-methylpyrrolidinone, N,N′-dimethylimidazolidinone, N,N-dimethylacetamide, cyclic ureas preferably 1,3-dimethyl-2-imidazolidinone or 1,3-dimethyl-3,4,5,6-tetrahydro-2(1H)-pyrimidinone, glymes preferably tetraglyme, sulfolane, sulfones such as (propane-2-sulfonyl)-benzene, 2-ethanesulfonyl-butane, 2-(2-methoxyethanesulfonyl)-propane, 2-(propane-2-sulfonyl)-butane, 3-methylsulfolane, dimethylsulfoxide, trimethylphosphate and methoxy-substituted nitriles. Other useful solvents are acetonitrile, benzonitrile and or valeronitrile.

If a solvent is present in the electrolyte formulation, there may further be comprised a polymer as gelling agent, wherein the polymer is polyvinylidenefluoride, polyvinylidene-hexafluropropylene, polyvinylidene-hexafluoropropylene-chlorotrifluoroethylene copolymers, nation, polyethylene oxide, polymethylmethacrylate, polyacrylonitrile, polypropylene, polystyrene, polybutadiene, polyethyleneglycol, polyvinylpyrrolidone, polyaniline, polypyrrole, polythiophene. The purpose of adding these polymers to electrolyte formulations is to make liquid electrolytes into quasi-solid or solid electrolytes, thus improving solvent retention, especially during aging.

In one embodiment of the invention, the electrolyte formulation according to the invention comprises merely an organic solvent and further additives such as lithium salts, guanidinium thiocyanates or classical additives such as a compound containing a nitrogen atom having non-shared electron pairs, e.g. N-alkylbenzimidazoles or alkyl-pyridines and bases having pKa between 3 to 6.

Lithium salts may be selected from the group lithium tetrafluoroborate, lithium perchlorate, lithium thiocyanate, lithium tetracyanoborate, lithium trifluoromethanesulfonate, lithium hexafluorophosphate, lithium tris(perfluororalkyl)trifluorophosphates, lithium bis(perfluoroalkyl)tetrafluorophosphates, lithium mono(perfluoroalkyl)pentafluorophosphates or lithium perfluoroalkylfluoroborate, wherein the perfluoroalkyl groups each independently are straight-chain or branched perfluoroalkyl groups having 1 to 10 C atoms, preferably 2 to 4 C atoms.

In another embodiment of the invention, the electrolyte formulation according to the invention comprises an organic solvent in less than 50%, and further comprising an ionic liquid as solvent. Preferably, the electrolyte formulation comprises less than 40%, more preferably less than 30%, still more preferably less than 20% and even less than 10% organic solvent. Most preferably, the electrolyte formulation comprises less than 5% of an organic solvent. For example, it is substantially free of an organic solvent. Percentages are indicated on the basis of weight %.

Ionic liquids or liquid salts are ionic species which consist of an organic cation and a generally inorganic anion. They do not contain any neutral molecules and usually have melting points below 373 K.

Preferred ionic liquids have organic cations comprising a quaternary nitrogen and an anion selected from a Br⁻, Cl⁻, a polyhalide ion, a fluoroalkanesulfonate, a fluoroalkanecarboxylate, a tris(fluoroalkylsulfonyl)methide, a bis(fluoroalkylsulfonyl)imide, bis(fluorsulfonyl)imide, a nitrate, a hexafluorophosphate, a tris-, bis- and mono-(fluoroalkyl)fluorophosphate, a tetrafluoroborate, a dicyanamide, a tricyanomethide, a tetracyanoborate, a perfluoroalkylfluoroborate, perfluoroalkylfluorocyanoborate, a thiocyanate, an alkylsulfonate or an alkylsulfate, with fluoroalkane-chain having 1 to 20 C atoms, preferably perfluorinated, fluoroalkyl having 1 to 20 C atoms and alkyl having 1 to 20 C atoms. Fluoroalkane-chain or fluoroalkyl is preferably perfluorinated.

Preferred ionic liquids have additionally the same anion [BX_{z}(CN)_{4-Z},]⁻ as defined for the at least one compound of formula (I) as described herein.

Particularly preferred ionic liquids have cations chosen from the group of 1,1-dialkylpyrrolidinium cations, for example, 1,1-dimethylpyrrolidinium, 1-methyl-1-ethylpyrrolidinium, 1-methyl-1-propylpyrrolidinium, 1-methyl-1-butylpyrrolidinium, 1-methyl-1-pentylpyrrolidinium, 1-methyl-1-hexylpyrrolidinium, 1-methyl-1-heptylpyrrolidinium, 1-methyl-1-octylpyrrolidinium, 1-methyl-1-nonylpyrrolidinium, 1-methyl-1-decylpyrrolidinium, 1,1-diethyl-pyrrolidinium, 1-ethyl-1-propylpyrrolidinium, 1-ethyl-1-butylpyrrolidinium, 1-ethyl-1-pentylpyrrolidinium, 1-ethyl-1-hexylpyrrolidinium, 1-ethyl-1-heptylpyrrolidinium, 1-ethyl-1-octylpyrrolidinium, 1-ethyl-1-nonylpyrrolidinium, 1-ethyl-1-decylpyrrolidinium, 1,1-dipropylpyrrolidinium, 1-propyl-1-methyl-pyrrolidinium, 1-propyl-1-butylpyrrolidinium, 1-propyl-1-pentylpyrrolidinium, 1-propyl-1-hexylpyrrolidinium, 1-propyl-1-heptylpyrrolidinium, 1-propyl-1-octylpyrrolidinium, 1-propyl-1-nonylpyrrolidinium, 1-propyl-1-decylpyrrolidinium, 1,1-dibutylpyrrolidinium, 1-butyl-1-methylpyrrolidinium, I-butyl-1-pentylpyrrolidinium, 1-butyl-1-hexylpyrrolidinium, 1-butyl-1-heptylpyrrolidinium, 1-butyl-1-octylpyrrolidinium, 1-butyl-1-nonylpyrrolidinium, 1-butyl-1-decylpyrrolidinium, 1,1-dipentylpyrrolidinium, 1-pentyl-1-hexylpyrrolidinium, 1-pentyl-1-heptylpyrrolidinium, 1-pentyl-1-octylpyrrolidinium, 1-pentyl-1-nonylpyrrolidinium, 1-pentyl-1-decylpyrrolidinium, 1,1-dihexyl-pyrrolidinium, 1-hexyl-1-heptylpyrrolidinium, 1-hexyl-1-octylpyrrolidinium, 1-hexyl-1-nonylpyrrolidinium, 1-hexyl-1-decylpyrrolidinium, 1,1-dihexyl-pyrrolidinium, 1-hexyl-1-heptylpyrrolidinium, 1-hexyl-1-octylpyrrolidinium, 1-hexyl-1-nonylpyrrolidinium, 1-hexyl-1-decylpyrrolidinium, 1,1-diheptyl-pyrrolidinium, 1-heptyl-1-octylpyrrolidinium, 1-heptyl-1-nonylpyrrolidinium, 1-heptyl-1-decylpyrrolidinium, 1,1-dioctylpyrrolidinium, 1-octyl-1-nonylpyrrolidinium, 1-octyl-1-decylpyrrolidinium, 1,1-dinonylpyrrolidinium, 1-nonyl-1-decylpyrrolidinium or 1,1-didecylpyrrolidinium. Very particular preference is given to 1-butyl-1-methylpyrrolidinium or 1-propyl-1-methyl-pyrrolidinium, 1-alkyl-1-alkoxyalkylpyrrolidinium cations, for example, 1-methoxymethyl-1-methyl-pyrrolidinium, 1-methoxymethyl-1-ethyl-pyrrolidinium, 1-(2-methoxyethyl)-1-methylpyrrolidinium, 1-(2-methoxyethyl)-1-ethylpyrrolidinium, 1-(2-methoxyethyl)-1-propylpyrrolidinium, 1-(2-methoxyethyl)-1-butylpyrrolidinium, 1-(2-ethoxyethyl)-1-methylpyrrolidinium, 1-ethoxymethyl-1-methylpyrrolidinium, 1-ethoxymethyl-1-ethyl-pyrrolidinium. Very particular preference is given to 1-(2-methoxyethyl)-1-methylpyrrolidinium, 1,3-dialkylimidazolium cations, for example, 1-ethyl-3-methylimidazolium, 1-methyl-3-propylimidazolium, 1,2,3-trimethylimidazolium, 1-ethyl-2,3-dimethylimidazolium, 1-propyl-2,3-dimethylimidazolium, 1-butyl-2,3-dimethylimidazolium, 1-butyl-3-methyl-imidazolium, 1-methyl-3-pentylimidazolium, 1-ethyl-3-propylimidazolium, 1-butyl-3-ethylimidazolium, 1-ethyl-3-pentylimidazolium, 1-butyl-3-propylimidazolium, 1,3-dimethylimidazolium, 1,3-diethylimidazolium, 1,3-dipropylimidazolium, 1,3-dibutylimidazolium, 1,3-dipentylimidazolium, 1,3-dihexylimidazolium, 1,3-diheptylimidazolium, 1,3-dioctylimidazolium, 1,3-dinonylimidazolium, 1,3-didecylimidazolium, 1-hexyl-3-methylimidazolium, 1-heptyl-3-methylimidazolium, 1-methyl-3-octylimidazolium, 1-methyl-3-nonylimidazolium, I-decyl-3-methylimidazolium, 1-ethyl-3-hexyl-imidazolium, 1-ethyl-3-heptylimidazolium, 1-ethyl-3-octylimidazolium, 1-ethyl-3-nonylimidazolium or 1-decyl-3-ethylimidazolium. Particularly preferred cations are 1-ethyl-3-methylimidazolium, 1-butyl-3-methyl-imidazolium or 1-methyl-3-propylimidazolium, 1-alkoxyalkyl-3-alkylimidazolium cations, for example 1-methoxymethyl-3-methylimidazolium, 1-methoxymethyl-3-ethylimidazolium, 1-methoxymethyl-3-butylimidazolium, 1-(2-methoxyethyl)-3-methylimidazolium, 1-(2-methoxyethyl)-3-ethylimidazolium, 1-(2-methoxyethyl)-3-propylimidazolium, 1-(2-methoxyethyl)-3-butylimidazolium, 1-(2-ethoxyethyl)-3-methyl-imidazolium, 1-ethoxymethyl-3-methylimidazolium and 1-alkenyl-3-alkylimidazolium cations, for example 1-allyl-3-methyl-imidazolium or 1-allyl-2,3-dimethylimidazolium and the anions are selected as described before.

Preferably, the ionic liquids are selected from salts comprising cations as described above and anions such as thiocyanate, tetracyanoborate, perfluoroalkylfluoroborate, perfluoroalkylfluorocyanoborate or anions of formula [BX_{z}(CN)_{4-z}]⁻, wherein X and z have a meaning as described for compounds of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D).

The electrolyte formulation of the invention may further comprise metal oxide nanoparticles like SiO₂, TiO₂, Al₂O₃, MgO or ZnO, for example, which are also capable of increasing solidity and thus solvent retention.

In another embodiment, the electrolyte formulation of the present invention further comprises at least one compound containing a nitrogen atom having non-shared electron pairs. Examples of such compounds are found in EP 0 986 079 A2, starting on page 2, lines 40-55, and again from page 3, lines 14 extending to page 7, line 54, which are expressly incorporated herein by reference. Preferred examples of compounds having non-shared electron pairs include imidazole and its derivatives, particularly benzimidazole and its derivatives.

The electrolyte formulation of the invention has many applications. For example, it may be used in an optoelectronic and/or electrochemical device such as a photovoltaic cell, a light emitting device, an electrochromic or photo-electrochromic device, an electrochemical sensor and/or biosensor.

The present invention therefore relates furthermore to an electrochemical and/or optoelectronic device comprising a first and a second electrode and, between said first and second electrode, a charge transport layer comprising at least one compound of formula (I) or at least one compound of formula (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) as described or preferably described in detail before.

The present invention therefore relates furthermore to an electrochemical and/or optoelectronic device comprising a first and a second electrode and, between said first and second electrode, a charge transport layer comprising at least one Co^{II}/Co^{III}-redox couple of formula (I) as described or preferably described in detail before or at least one Co^{II}/Co^{III}-redox couple of formula (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) as described or preferably described in detail before.

Preferably, the device according to the invention is a photoelectric conversion device, preferably a photovoltaic cell, particularly preferably a dye-sensitized solar cell or a solid state dye-sensitized solar cell.

Preferably, the charge transport layer of the device according to the invention comprises an organic solvent and/or comprises one or more ionic liquids.

Organic solvents and ionic liquids are described in detail before.

The charge transport layer of the device according to the invention is in one embodiment of the invention the electrolyte formulation according to the invention as described or preferably described in detail before or with other words the charge transport layer is a solvent and/or ionic liquid based electrolyte or a solid electrolyte, preferably a solvent and/or ionic liquid based electrolyte.

Therefore, the invention additionally relates to the electrochemical and/or optoelectronic device wherein the at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) is contained in the electrolyte formulation or with other words, the electrochemical and/or optoelectronic device comprises the electrolyte formulation according to the invention as described and preferably described before.

According to another embodiment of the invention, the at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D), as described or preferably described before, can be used as dopant in a charge transporting material building the charge transport layer of the device according to the invention. The charge transport material is preferably an organic, electronically conducting charge transporting material, in which electrons and/or holes move by electronic motion, instead of diffusion of charged molecules. Such electrically conductive layers may, for example, be based on organic compounds, including polymers.

The charge transport layer may therefore be an electron and/or hole conducting material. The at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) as described or preferably described before, are useful dopants for triarylamine-based hole conductors.

The at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) as described or preferably described before in which n is 3, are useful p-type dopants for triarylamine-based hole conductors.

Triarylamine-based hole conductors are known in the art. One important hole conductor is 2,2′,7,7′-tetrakis(N,N-di-p-methoxyphenyl-amine)9,9′-spirobifluorene, also known as spiro-MeOTAD.

Therefore, the invention additionally relates to the use of at least one compound of formula (I), (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D) as described or preferably described before, in which n is 3 as p-type dopant for triarylamine-based hole conductors, preferably for spiro-MeOTAD.

Additionally, the invention relates to a method of preparing an electrochemical device and/or optoelectronic device as described or preferably described before, the method comprising the steps of:
providing a first and a second electrode;
providing a charge transport layer,

adding to said charge transport layer at least one compound of formula (I), wherein Y₁, Y₂, c, X, z, y, R and n have meaning as described or preferably described before.

Additionally, the invention relates to a method of preparing an electrochemical device and/or optoelectronic device as described or preferably described before, the method comprising the steps of:
providing a first and a second electrode;
providing a charge transport layer,

adding to said charge transport layer at least one compound of formula (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D), wherein Y₁, Y₂, c, X, z, y, R and n have meaning as described or preferably described before.

Preferably, the invention relates to a method of preparing an electrochemical device and/or optoelectronic device as described or preferably described before, the method comprising the steps of:
providing a first and a second electrode;
providing a charge transport layer,
adding to said charge transport layer at least one Co^{II}/Co^{III}-redox couple of formula (I), wherein Y₁, Y₂, c, X, z, y and R are identical or different as described or preferably described before.

Preferably, the invention relates to a method of preparing an electrochemical device and/or optoelectronic device as described or preferably described before, the method comprising the steps of:
providing a first and a second electrode;
providing a charge transport layer,

adding to said charge transport layer at least one Co^{II}/Co^{III}-redox couple of formula (IA), (IB), (IC), (ID), (I-1), (I-1A), (I-1B), (I-1C), (I-1D), (I-2), (I-2A), (I-2B), (I-2C), (I-2D), (I-3), (I-3A), (I-3B), (I-3C) or (I-3D), wherein Y₁, Y₂, c, X, z, y and R are identical or different as described or preferably described before.

Dye sensitized solar cells are disclosed in U.S. Pat. No. 6,861,722, for example. In dye-sensitized solar cells, a dye is used to absorb the sunlight to convert into the electrical energy. There are no restrictions per se with respect to the choice of the sensitizing dye as long as the LUMO energy state is marginally above the conduction bandedge of the photoelectrode to be sensitized. Examples of dyes are disclosed in Nanoenergy, de Souza, Flavio Leandro, Leite, Edson Roberto (Eds.), Springer, ISBN 978-3-642-31736-1, pages 58 to 74, black dyes as described in U.S. Pat. No. 8,383,553 or dyes as disclosed in EP 0 986 079 A2, EP 1 180 774 A2 or EP 1 507 307 A1.

Preferred dyes are organic dyes such as MK-1, MK-2 or MK-3 (its structures are described in FIG. 1 of N. Koumura et al, J.Am.Chem.Soc. Vol 128, no. 44, 2006, 14256-14257), D29 as described on page 4 of WO 2012/001033, D35 as described on page 4 of WO 2012/001033, D102 (CAS no. 652145-28-3), D-149 (CAS no. 786643-20-7), D205 (CAS no. 936336-21-9), D358 (CAS no. 1207638-53-6), YD-2 as described in T. Bessho et al, Angew. Chem. Int. Ed. Vol 49, 37, 6646-6649, 2010, Y123 (CAS no. 1312465-92-1), bipyridin-Ruthenium dyes such as N3 (CAS no. 141460-19-7), N719 (CAS no. 207347-46-4), Z907 (CAS no. 502693-09-6), C101 (CAS no. 1048964-93-7), C106 (CAS no. 1152310-69-4), K19 (CAS no. 847665-45-6), HRS-1 (CAS no. 906061-30-1 as disclosed in K. J. Jiang et al, Chem. Comm. 2460, 2006) or terpyridine-Ruthenium dyes such as N749 (CAS no. 359415-47-7).

The structure of D205 is

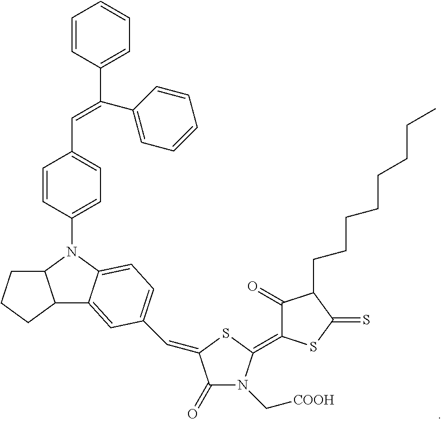 [SMILES: CCCCCCCCC1C(=O)/C(=c2\s/c(=C\c3ccc4c(c3)C3CCCC3N4c3ccc(C=C(c4ccccc4)c4ccccc4)cc3)c(=O)n2CC(=O)O)SC1=S]

The structure of D358 is

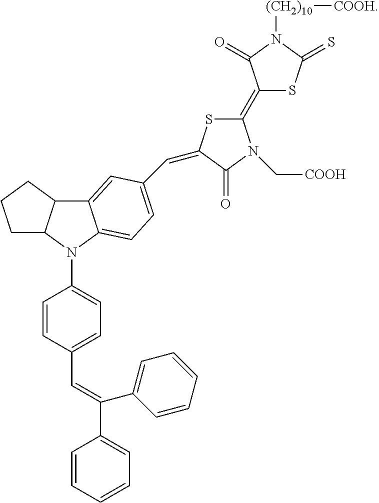

Particularly preferred dyes are Z907 or Z907Na which are both an amphiphilic ruthenium sensitizer, D29, D35, Y123, C106, D358 or HRS-1. The dye Z907Na means NaRu(2,2′-bipyridine-4-carboxylic acid-4′-carboxylate)(4,4′-dinonyl-2,2′-bipyridine)(NCS)₂.

A very particular dye is D358.

For example, a dye-sensitized solar cell comprises a photo-electrode, a counter electrode and, between the photo-electrode and the counter electrode, an electrolyte formulation or a charge transporting material, and wherein a sensitizing dye is absorbed on the surface of the photo-electrode, on the side facing the counter electrode.

According to a preferred embodiment of the device according to the invention, it comprises a semiconductor, the electrolyte formulation as described above and a counter electrode.

According to a preferred embodiment of the invention, the semiconductor is based on material selected from the group of Si, TiO₂, SnO₂, Fe₂O₃, WO₃, ZnO, Nb₂O₅, CdS, ZnS, PbS, Bi₂S₃, CdSe, GaP, InP, GaAs, CdTe, CuInS₂, and/or CuInSe₂. Preferably, the semiconductor comprises a mesoporous surface, thus increasing the surface optionally covered by a dye and being in contact with the electrolyte. Preferably, the semiconductor is present on a glass support or plastic or metal foil. Preferably, the support is conductive.

The device of the present invention preferably comprises a counter electrode. For example, fluorine doped tin oxide or tin doped indium oxide on glass (FTO- or ITO-glass, respectively) coated with Pt, carbon of preferably conductive allotropes, polyaniline or poly (3,4-ehtylenedioxythiophene) (PEDOT). Metal substrates such as stainless steel or titanium sheet may be possible substrates beside glass.

The device of the present invention in which the charge transport layer is a solvent and/or ionic liquid based electrolyte formulation may be manufactured as the corresponding device of the prior art by simply replacing the electrolyte by the electrolyte formulation of the present invention. For example, in the case of dye-sensitized solar cells, device assembly is disclosed in numerous patent literature, for example WO 91/16719 (examples 34 and 35), but also scientific literature, for example in Barbé, C. J., Arendse, F., Comte, P., Jirousek, M., Lenzmann, F., Shklover, V., Grätzel, M. J. Am. Ceram. Soc. 1997, 80, 3157; and Wang, P., Zakeeruddin, S. M., Comte, P., Charvet, R., Humphry-Baker, R., Grätzel, M. J. Phys. Chem. B 2003, 107, 14336.

Preferably, the sensitized semi-conducting material serves as a photoanode. Preferably, the counter electrode is a cathode.

The present invention also provides a method for preparing a photoelectric cell comprising the step of bringing the electrolyte formulation of the invention in contact with a surface of a semiconductor, said surface optionally being coated with a sensitizer. Preferably, the semiconductor is selected from the materials given above, and the sensitizer is preferably selected from a dye as disclosed above.

Preferably, the electrolyte formulation may simply be poured on the semiconductor. Preferably, it is applied to the otherwise completed device already comprising a counter electrode by creating a vacuum in the internal lumen of the cell through a hole in the counter electrode and adding the electrolyte formulation as disclosed in the reference of Wang et al., J. Phys. Chem. B 2003, 107, 14336.

The present invention will now be illustrated, without limiting its scope, by way of the following examples. Even without further comments, it is assumed that a person skilled in the art will be able to utilise the above description in the broadest scope. The preferred embodiments and examples should therefore merely be regarded as descriptive disclosure which is absolutely not limiting in any way.

### EXAMPLES

The substances were characterised by means of NMR. The NMR-spectra are measured in deuterated solvent CD₃CN by use of Bruker Avance III Spektrometer with Deuterium Lock. The resonance frequency for different nuclear are: ¹H: 400.17 MHz, ¹¹B: 128.39 MHz and ¹³C: 100.61 MHz. The following references are used: TMS for ¹H and ¹³C spectra and BF₃.Et₂O— for ¹¹B spectra.

Cyclic voltammograms are measured in the 5 ml glass cell equipped with ESA EE047 glassy carbon working electrode (internal diameter: 3 mm; electrochemically active area: 7.1 mm²), Pt counter electrode (Pt-wire, ø 0.5 mm, 57 mm long; electrochemically active area: 78.5 mm²) and RE-7 non-aqueous reference electrode Ag/Ag⁺ (0.01 M AgNO₃ in CH₃CN). All measurements are carried out in acetonitrile as solvent. Tetrabutyl ammonium hexafluorophosphate, [TBA][PF₆], with the concentration 0.1 mol/L in CH₃CN is used as supporting electrolyte. The concentration of the test substance (Co-complexes) in all measurements is 1·10⁻³ mol/L. The volume of the solution in the cell is 4 ml. Reference substance is decamethylferrocene (E°=−0.423 V). The values of oxidation/reduction potentials and E° are given comparatively to Ag/Ag⁺ (0.01 M AgNO₃ in CH₃CN) reference electrode. The following data are reported: E_{pC} (cathodic peak); E_{pA} (anodic peak); E°—standard potential for reversible redox couple Co⁺²/Co⁺³.

The potentiostat Autolab PGSTAT30 (Fa. Metrom) is used for recording of cyclic voltammograms. Scan rate is 15 mV·s⁻¹.

In the Examples below bp-pz, 6-(N-pyrazolyl)2,2″-bipyridine, means:

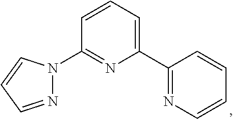 [SMILES: c1ccc(-c2cccc(-n3cccn3)n2)nc1]

py-bipz, 2,6-bis(N-pyrazolyl)pyridine, means:

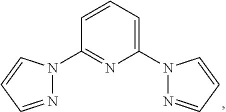 [SMILES: c1cc(-n2cccn2)nc(-n2cccn2)c1]

terpy (2,2″:6″; 2″-Terpyridine) means:

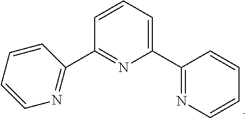 [SMILES: c1ccc(-c2cccc(-c3ccccn3)n2)nc1]

### Example 1

### Synthesis of [Co(bp-pz)₂][BH(CN)₃]₂

2K[BH(CN)₃]+2bp-pz+CoCl₂.6H₂O→[Co(bp-pz)₂][BH(CN)₃]₂+2KCl

0.105 g (0.441 mmol) CoCl₂.6H₂O dissolved in 7 mL of water and 0.195 g (0.880 mmol) bp-pz in 20 mL of ethanol are mixed together at room temperature. The reaction mixture is stirred for 3 hours and the solution of 0.114 g (0.884 mmol) K[BH(CN)₃] in 5 mL of water is added. In 30 min the reaction mixture is diluted with 40 mL of water and cooled down with an ice-bath. The product precipitates. It is filtered off, washed two times with 5 mL of water and two times with 10 mL of Et₂O. The product is dried in vacuum at room temperature. An additional quantity of the product precipitated from the mother-solution in time.

The structure of the product, [Co(bp-pz)₂][BH(CN)₃]₂, is confirmed by the NMR-spectra.

NMR ¹H, δ, ppm:

[BH(CN)₃]⁻: 1.60 broad.

### Example 2

### Synthesis of [Co(bp-pz)₂][BH(CN)₃]₃

3K[BH(CN)₃]+2bp-pz+CoCl₂.6H₂O+Cl₂→[Co(bp-pz)₂][BH(CN)₃]₃+3KCl

0.124 g (0.521 mmol) CoCl₂.6H₂O dissolved in 10 mL of water are mixed together with 0.231 g (1.040 mmol) bp-pz in 20 mL of ethanol. In 30 min Cl₂-gas is bubbled through the reaction mixture for 20 min. The bubbling of the Chlorine is finished after the colour of the solution doesn't change any more. The residue of Cl₂ is removed under vacuum and 0.201 g (1.560 mmol) K[BH(CN)₃] dissolved in 20 mL of water are added to the reaction mixture. The coloured solid precipitates from the solution. It is filtered off, washed with two times with 5 mL of water and two times with 15 mL of Et₂O. The product is dried in vacuum at room temperature.

An additional quantity of the product precipitated from the mother-solution in time.

The structure of the product, [Co(bp-pz)₂][BH(CN)₃]₃, is confirmed by the NMR-spectra.

NMR ¹¹B, δ, ppm:

[BH(CN)₃]⁻: −40.0 d, ¹J_{B,H}=97 Hz, ¹J_{B,C}=66 Hz;

NMR ¹H, δ, ppm:

[BH(CN)₃]⁻: 1.71 q (¹¹B), sep (¹⁰B), ¹J_{11B,H}=98 Hz, ¹J_{10B,H}=33 Hz.

### Example 3

### Synthesis of [Co(bp-pz)₂][BF(CN)₃]₂

2K[BF(CN)₃]+2bp-pz+CoCl₂.6H₂O→[Co(bp-pz)₂][BF(CN)₃]₂+2KCl

0.125 g (0.525 mmol) CoCl₂.6H₂O dissolved in 10 mL of water and 0.233 g (1.050 mmol) bp-pz in 20 mL of ethanol are mixed together at room temperature. The reaction mixture is stirred for 3 hours and the solution of 0.155 g (1.055 mmol) K[BF(CN)₃] in 10 mL of water is added. In 30 min the reaction mixture is diluted with 40 mL of water and cooled down with an ice-bath. The product precipitates. It is filtered off, washed two times with 5 mL of water and two times with 15 mL of Et₂O. The product is dried in vacuum at room temperature. An additional quantity of the product precipitates from the mother-solution in time.

The structure of the product, [Co(bp-pz)₂][BF(CN)₃]₂, is confirmed by by the NMR-spectra.

NMR ¹¹B, δ, ppm:

[BF(CN)₃]⁻: −18.0 d, ¹J_{11B,19F}=44 Hz, ¹J_{11B,13C}=75 Hz.

NMR ¹⁹F, δ, ppm:

[BF(CN)₃]⁻: −212 d, ¹J_{11B,19F}=44 Hz, ¹J_{10B,19F}=14.5 Hz.

### Example 4

### Synthesis of [Co(bp-pz)₂][BF(CN)₃]₃

3K[BF(CN)₃]+2bp-pz+CoCl₂.6H₂O+Cl₂→[Co(bp-pz)₂][BF(CN)₃]₃+3KCl

0.120 g (0.504 mmol) CoCl₂.6H₂O dissolved in 10 mL of water are mixed together with 0.223 g (1.005 mmol) bp-pz in 20 mL of ethanol. In 30 min Cl₂-gas is bubbled through the reaction mixture for 20 min. The bubbling of the Chlorine is finished after the colour of the solution doesn't change any more. To the reaction mixture 0.222 g (1.511 mmol) K[BF(CN)₃] dissolved in 20 mL of water are added to the reaction mixture. The coloured solid precipitates from the solution. It is filtered off, washed with two times with 5 mL of water and two times with 15 mL of Et₂O. The product is dried in vacuum at room temperature. An additional quantity of the product precipitates from the mother-solution in time.

The structure of the product, [Co(bp-pz)₂][BF(CN)₃]₃, is confirmed by the NMR-spectra.

NMR ¹¹B, δ, ppm:

[BF(CN)₃]⁻: −17.9 d, ¹J_{11B,19F}=44 Hz, ¹J_{11B,13C}=75 Hz.

NMR ¹⁹F, δ, ppm:

[BF(CN)₃]⁻: −212 d, ¹J_{11B,19F}=44 Hz, ¹J_{10B,19F}=14.5 Hz.

### Example 5

### Synthesis of [Co(terpy)₂][BF(CN)₃]₂

2K[BF(CN)₃]+2terpy+CoCl₂.6H₂O→[Co(terpy)₂][BF(CN)₃]₂+2KCl

0.120 g (0.504 mmol) CoCl₂.6H₂O dissolved in 10 mL of water and 0.233 g (1.00 mmol) terpy in 20 mL of ethanol are mixed together at room temperature. The reaction mixture is stirred for 3 hours and the solution of 0.148 g (1.010 mmol) K[BF(CN)₃] in 10 mL of water is added. In 30 min the reaction mixture is diluted with 40 mL of water and cooled down with an ice-bath. The product precipitates. It is filtered off, washed two times with 5 mL of water and two times with 15 mL of Et₂O. The product is dried in vacuum at room temperature. An additional quantity of the product precipitates from the mother-solution in time.

The structure of the product, [Co(terpy)₂][BF(CN)₃]₂, is confirmed by the NMR-spectra.

NMR ¹¹B, δ, ppm:

[BF(CN)₃]⁻: −18.0 d, ¹J_{11B,19F}=44 Hz, ¹J_{11B,13C}=75 Hz.

NMR ¹⁹F, δ, ppm:

[BF(CN)₃]⁻: −212 d, ¹J_{11B,19F}=44 Hz, ¹J_{10B,19F}=14.5 Hz.

Cyclic Voltammetry:

E_{pA}=0.035 V; E°_{co+2/Co+3}=0.040 V (reversible redox system)

Elemental analysis, %. found: C, 58.08; H, 3.00; N, 22.45; calculated: C, 58.34; H, 2.99; N, 22.68.

### Example 6

### Synthesis of [Co(terpy)₂][BF(CN)₃]₃

3K[BF(CN)₃]+3terpy+CoCl₂.6H₂O+Cl₂→[Co(terpy)₂][BF(CN)₃]₃+3KCl

0.105 g (0.441 mmol) CoCl₂.6H₂O dissolved in 10 mL of water are mixed together with the solution of 0.199 g (0.852 mmol) terpy in 20 mL of ethanol. In 30 min Cl₂-gas is bubbled through the reaction mixture for 20 min. The bubbling of the Chlorine is finished after the colour of the solution doesn't change any more. To the reaction mixture 0.192 g (1.305 mmol) K[BF(CN)₃] dissolved in 20 mL of water are added to the reaction mixture. The coloured solid precipitates from the solution. It is filtered off, washed with two times with 5 mL of water and two times with 15 mL of Et₂O. The product is dried in vacuum at room temperature. An additional quantity of the product precipitates from the mother-solution in time.

The structure of the product, [Co(terpy)₂][BF(CN)₃]₃, was confirmed by the NMR-spectra.

NMR ¹¹B, δ, ppm:

[BF(CN)₃]⁻: −17.9 d, ¹J_{11B,19F}=44 Hz, ¹J_{11B,13C}=75 Hz.

NMR ¹⁹F, δ, ppm:

[BF(CN)₃]⁻: −212 d, ¹J_{11B,19F}=44 Hz, ¹J_{10B,19F}=14.5 Hz.

### Example 7

### Synthesis of [Co(py-bipz)₂][BH(CN)₃]₂

2K[BH(CN)₃]+2py-bipz+CoCl₂.6H₂O→[Co(bp-pz)₂][BH(CN)₃]₂+2KCl

95 mg (0.399 mmol) CoCl₂.6H₂O dissolved in 15 mL of water and 165 mg (0.781 mmol) py-bipz in 20 mL of acetone are mixed together at room temperature. The reaction mixture is stirred for 1 hour and the solution of 104 mg (0.806 mmol) K[BH(CN)₃] in 10 mL of water is added. In 30 min the reaction mixture is diluted with 40 mL of water and cooled down with an ice-bath. The product precipitates. It is filtered off, washed two times with 5 mL of water and two times with 10 mL of Et₂O. The product is dried in vacuum at room temperature. An additional quantity of the product precipitates from the mother-solution in time.

The structure of the product, [Co(py-bipz)₂][BH(CN)₃]₂, is confirmed by the NMR-spectra.

NMR ¹H, δ, ppm:

[BH(CN)₃]⁻: 1.60 broad.

### Example 8

### Synthesis of [Co(py-bipz)₂][BH(CN)₃]₃

3K[BH(CN)₃]+2py-bipz+CoCl₂.6H₂O+Cl₂→[Co(py-bipz)₂][BH(CN)₃]₃+3KCl

64 mg (0.269 mmol) CoCl₂.6H₂O dissolved in 7 mL of water are mixed together with 112 mg (0.530 mmol) py-bipz in 20 mL of ethanol. In 30 min Cl₂-gas is bubbled through the reaction mixture for 20 min. The bubbling of the Chlorine is finished after the colour of the solution doesn't change any more. The residue of Cl₂ is removed under vacuum and 106 mg (0.822 mmol) K[BH(CN)₃] dissolved in 20 mL of water are added to the reaction mixture. The coloured solid precipitates from the solution. It is filtered off, washed two times with 5 mL of water and two times with 15 mL of Et₂O. The product is dried in vacuum at room temperature.

An additional quantity of the product precipitates from the mother-solution in time.

The structure of the product, [Co(py-bipz)₂][BH(CN)₃]₃, is confirmed by the NMR-spectra.

NMR ¹¹B, δ, ppm:

[BH(CN)₃]⁻: −40.0 d, ¹J_{B,H}=97 Hz, ¹J_{B,C}=66 Hz;

NMR ¹H, δ, ppm:

[BH(CN)₃]⁻: 1.71 q (¹¹B), sep (¹⁰B), ¹J_{11B,H}=98 Hz, ¹J_{10B,H}=33 Hz.

### Example 9

### Synthesis of [Co(terpy)₂][BH(CN)₃]₂

2K[BH(CN)₃]+2terpy+CoCl₂.6H₂O→[Co(terpy)₂][BH(CN)₃]₂+2KCl

0.075 g (0.317 mmol) CoCl₂.6H₂O and 0.148 g (0.633 mmol) terpy are mixed together at room temperature in 30 mL of water for 2 hours. After filtration 0.082 g (0.636 mmol) K[BH(CN)₃] in 10 mL of water is added to the reaction mixture. The reaction mixture is left stirred at room temperature over night (ca. 12). The precipitant is filtered off, washed two times with 2 mL of water and two times with 2 mL of Et₂O. The product is dried in vacuum at room temperature. 0.190 g (0.269 mmol; the yield is 85%) of solid material was obtained. The structure of the product, [Co(terpy)₂][BH(CN)₃]₂, is confirmed by the NMR-spectra.

NMR ¹¹B (Solvent: Aceton-D₆), δ, ppm:

[BH(CN)₃]⁻: −40.6 d, ¹J_{B,H}=97 Hz.

NMR ¹H (Solvent: Aceton-D₆), δ, ppm:

terpy: 98.90, 57.13, 48.01, 34.38, 22.25, 9.18.

[BH(CN)₃]⁻: 2.01 q, ¹J_{11B,H}=97 Hz.

Cyclic Voltammetry:

E_{pA}=0.011 V; E°_{Co+2/Co+3}=0.030 V (reversible redox system)

Elemental analysis, %. found: C, 60.78; H, 3.55; N, 23.31; calculated: C, 61.31; H, 3.43; N, 23.83.

### Example A

A double-layer, mesoporous TiO₂ electrode is prepared as disclosed in Wang P. et al., J. Phys. Chem. B 2003, 107, 14336, in particular page 14337, in order to obtain a photoanode consisting of a double layer structure. To prepare a transparent nanoporous TiO₂ electrode, a screen printing paste containing terpineol solvent and nanoparticulate TiO₂ of anatase phase with 30 nm diameter was deposited on a transparent conductive substrate to 5 mm×5 mm squared shape by using a screen printer. The paste was dried for 10 minutes at 120 degrees Celsius. Another screen printing paste containing TiO₂ with 400 nm diameter was then deposited on top of the nanoporous layer to prepare an opaque layer. The double layer film was then sintered at 500 degrees Celsius for an hour with the result of an underlying transparent layer (14 microns thick) and a top opaque layer (8 microns thick). After sintering, the electrode was immersed in 40 mM aqueous solution of TiCl₄ (Merck) for 30 minutes at 70 degrees Celsius and then rinsed quickly with pure water sufficiently. Thus TiCl₄-treated electrode was dried at 500 degrees Celsius for 30 minutes just before dye sensitization. The electrode was dipped into a 0.3 mM D358 dye solution of acetonitrile (Merck HPLC grade) and tert-butyl alcohol (Merck), v:v=1:1 for 60 hours at 19 degrees Celsius. The counter electrode was prepared with thermal pyrolysis method as disclosed in the reference above. A droplet of 5 mM solution of platinic acid (Merck) was casted at 8 μl/cm² and dried on a conductive substrate. The dye sensitized solar cell was assembled by using 30 micron thick Bynel (DuPont, USA) hot-melt film to seal up by heating. The internal space was filled with each of the electrolyte formulations as described herein to produce the corresponding devices.

The dye D358 is an indoline dye. Electrolyte used here is acetonitrile solution of 200 mM Cobaltcomplex salt of formula (I) in which n is 2, 40 mM Cobaltcomplex salt of formula (I) in which n is 3, 21 mM LiBF₄ and 150 mM N-butylbenzimidazole.

In order to obtain accurate light intensity level, Air Mass 1.5 Global (AM1.5G) simulated sunlight was calibrated spectrally according to Seigo Ito et al. “Calibration of solar simulator for evaluation of dye-sensitized solar cells” Solar Energy Materials & Solar Cells 82 (2004) 421. The measurements of photocurrent-voltage curves are carried out for devices placed on a black plate chilled down to 25° C. under 1 Sun illumination. A photomask of 4 mm×4 mm is placed on top of the fabricated devices to define the light projection area. Energy conversion efficiency is generally the ratio between the useful output of an energy conversion machine and the input of light radiation, in energy terms, determined by using adjustable resistant load to optimize the electric power output.

J_{SC}=short circuit current

V_{OC}=open circuit voltage

FF=fill factor

η=power conversion efficiency

1. Compounds of formula (I) 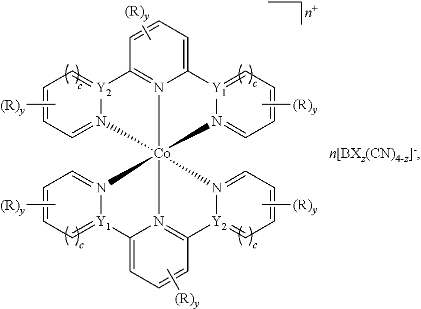
in which
X is H or F,
Y₁ and Y₂ are each independently C or N,
c is 0 in the case Y₁ and/or Y₂ are N,
c is 1 in the case Y₁ and/or Y₂ are C,
z is 1 or 2,
n is 2 or 3,
y is each independently 0, 1, 2, 3 or 4,
R is each independently a straight-chain or branched alkyl group with 1 to 20 C atoms.

2. Compounds according to claim 1, wherein R is each independently a straight-chain or branched alkyl group with 1 to 10 C atoms.

3. Compounds according to claim 1, wherein y is 0 or 1.

4. Process for the preparation of a compound of formula (I) in which n is 2 according to claim 1 comprising the reaction of a compound of formula (II)
Kt[BX_{z}(CN)_{4-Z}] (II),
in which
X is H or F,
z is 1 or 2 and
Kt is an alkali metal cation
with Cobalt dichloride or a hydrate thereof and with at least two equivalents of a compound of formula (III) 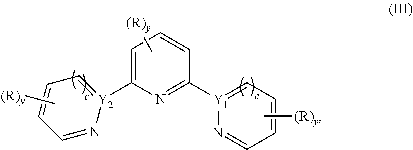
in which
Y₁ and Y₂ are each independently C or N,
c is 0 in the case Y₁ and/or Y₂ are N,
c is 1 in the case Y₁ and/or Y₂ are C,
y is each independently 0, 1, 2, 3 or 4,
R is each independently a straight-chain or branched alkyl group with 1 to 20 C atoms.

5. Process for the preparation of a compound of formula (I) in which n is 3 according to claim 1 comprising the reaction of a compound of formula (II)
Kt[BX_{z}(CN)_{4-Z}] (II),
in which
X is H or F,
z is 1 or 2 and
Kt is an alkali metal cation
with Cobalt dichloride or a hydrate thereof and with at least two equivalents of a compound of formula (III) 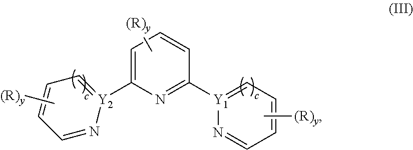
in which
Y₁ and Y₂ are each independently C or N,
c is 0 in the case Y₁ and/or Y₂ are N,
c is 1 in the case Y₁ and/or Y₂ are C,
y is each independently 0, 1, 2, 3 or 4,
R is each independently a straight-chain or branched alkyl group with 1 to 20 C atoms,
in the presence of an oxidant.

6. An electroyte formulation comprising at least one compound of formula (I) according to claim 1.

7. The electrolyte formulation according to claim 6 comprising the at least one compound of formula (I) in concentrations from 0.01 M to 0.5 M, preferably from 0.05 M to 0.3 M.

8. An electrochemical and/or optoelectronic device comprising a first and a second electrode and, between said first and second electrode, a charge transport layer comprising at least one compound of formula (I) according to claim 1.

9. An electrochemical and/or optoelectronic device comprising a first and a second electrode and, between said first and second electrode, a charge transport layer comprising at least one Co^{II}/Co^{III}-redox couple of formula (I), wherein X, y, R, m and R′ are identical or different and are defined according to claim 1.

10. The device according to claim 8 which is a photoelectric conversion device, preferably a dye-sensitized solar cell or a solid state dye-sensitized solar cell.

11. The device according to claim 8, wherein said charge transport layer comprises an organic solvent and/or comprises one or more ionic liquids.

12. The device according to claim 8, wherein at least one compound of formula (I) is contained in the electrolytic solution.

13. Use of compounds of formula (I) according to claim 1 in which n is 3 as p-type dopants for triarylamine-based hole conductors.

14. A method of preparing an electrochemical device according to claim 8, the method comprising the steps of:
providing a first and a second electrode;
providing a charge transport layer,
adding to said charge transport layer at least one compound of formula (I).

15. A method of preparing an electrochemical device according to claim 9, the method comprising the steps of:
providing a first and a second electrode;
providing a charge transport layer,
adding to said charge transport layer at least one Co^{II}/Co^{III}-redox couple of formula (I), wherein Y₁, Y₂, c, X, y, and z are identical or different and are defined according to one or more of claims 1 to 3.
